(19) United States
(12) Patent Application Publication
(10) Pub. No.: US 2025/0351613 A1
(43) Pub. Date: Nov. 13, 2025

(54) PHOTONIC DEVICE FORMED USING SELF-ALIGNED PROCESSES

(71) Applicant: Taiwan Semiconductor Manufacturing Company, Ltd., Hsin-Chu (TW)

(72) Inventors: Chun-Yen Peng, Hsinchu (TW); Hau-Yan Lu, Hsinchu City (TW); Yingkit Felix Tsui, Cupertino, CA (US)

(21) Appl. No.: 19/275,552

(22) Filed: Jul. 21, 2025

Related U.S. Application Data
(63) Continuation of application No. 18/512,686, filed on Nov. 17, 2023.
(60) Provisional application No. 63/519,509, filed on Aug. 14, 2023.

(51) Int. Cl. H10F 71/00; H10F 30/225; H10F 77/122; H10F 77/169

(52) U.S. Cl. CPC H10F 71/1212; H10F 30/225; H10F 77/122; H10F 77/169

(57) ABSTRACT

A photonic device includes a substrate, a P-type doped component disposed over the substrate, an N-type doped component disposed over the substrate, an optical absorption layer disposed over the substrate, and a charging layer disposed over the substrate. The optical absorption layer is disposed between the P-type doped component and the N-type doped component. The optical absorption layer and the substrate have different material compositions. A charging layer is disposed between the P-type doped component and the N-type doped component. The charging layer has a first side surface that is substantially linear. The first side surface is in direct contact with the optical absorption layer.

### PRIORITY DATA

This present application is a continuation of U.S. application Ser. No. 18/512,686 filed on Nov. 17, 2023, entitled “PHOTONIC DEVICE FORMED USING SELF-ALIGNED PROCESSES” which is claims benefit of U.S. Provisional Application 63/519,509, filed on Aug. 14, 2023, and entitled “SILICON PHOTONIC DEVICE”, the disclosures of each of which are hereby incorporated by reference in their respective entireties.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As semiconductor devices shrink in size but increase in sophistication, they can be deployed in a great variety of applications. These applications may include photonic devices, such as semiconductor image sensors that are used to sense radiation (e.g., visible light). For example, complementary metal-oxide-semiconductor (CMOS) image sensors (CIS) and charge-coupled device (CCD) sensors are widely used in various applications such as digital still cameras, mobile phones, medical devices, automobile sensors, etc. However, as device sizes become smaller, it may be more difficult to form certain components of the photonic devices with desired precision, for example, with respect to the size and/or location of these certain components. As a result, the performance of the photonic devices may be degraded. What is needed is an enhanced scheme to fabricate the components of photonic devices with sufficient precision with respect to their sizes and/or locations, even as semiconductor device sizes continue to shrink in each technology generation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A illustrates a planar top view of a semiconductor photonic device according to various aspects of the present disclosure.

FIG. 1B illustrates a graph corresponding to an electric field of a semiconductor photonic device according to various aspects of the present disclosure.

FIGS. 2-34 illustrate a series of cross-sectional side views of a semiconductor photonic device at various stages of fabrication corresponding to a process flow according to various aspects of the present disclosure.

FIG. 35 illustrates a planar top view of a photonic device according to various aspects of the present disclosure.

FIGS. 36A-36H illustrate a plurality of cross-sectional side views of a portion of a semiconductor photonic device corresponding to a plurality of embodiments according to various aspects of the present disclosure.

FIG. 37 illustrates a series of cross-sectional side views of a semiconductor photonic device at various stages of fabrication corresponding to a process flow according to various aspects of the present disclosure.

FIG. 38 illustrates a flowchart illustrating a method of fabricating a photonic device according to various aspects of the present disclosure.

FIG. 39 illustrates a block diagram of an integrated circuit fabrication system according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one feature relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to semiconductor photonic devices. For example, the present disclosure introduces a scheme to fabricate avalanche photodiode (APD) through a self-aligned process. Using such a self-alignment process, the resulting APD can achieve a narrow width for its doped regions (e.g., for a charging layer), as well as a substantially vertical doping profile for the portion of the doped region that is disposed directly adjacent to an optical absorption layer. The various aspects of the present disclosure will now be discussed below in more detail.

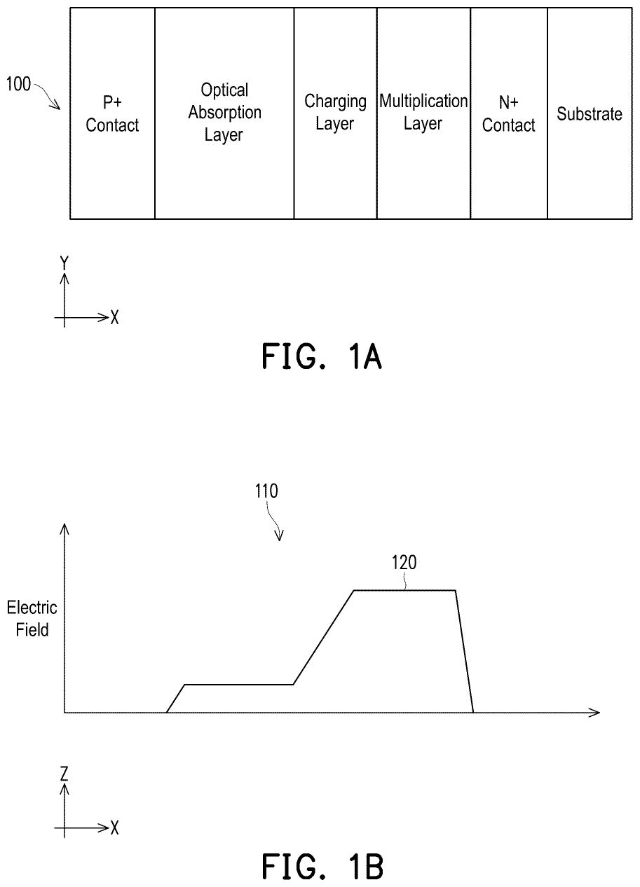

Referring now to FIGS. 1A and 1B, a diagrammatic fragmentary planar top view of a portion of an APD 100 and a graph 110 corresponding to the APD 100 are illustrated. The APD 100 in FIG. 1A has an X-axis spanning a first horizontal direction and a Y-axis spanning a second horizontal direction. The APD 100 includes a plurality of components that are arranged next to one another along the X-axis. For example, the APD 100 includes a P+ contact, an optical absorption layer, a charging layer, a multiplication layer, an N+ contact, and a substrate. The substrate may be a portion of a semiconductor substrate. For example, the substrate may contain a silicon material. The P+ contact may include silicon that is doped with a P-type dopant, and the N+ contact may include silicon that is doped with an N-type dopant. The P+ contact and the N+ contact may serve as the P-type region and the N-type region of a P-N diode. The optical absorption layer—which may include a germanium material in some embodiments—is configured to absorb radiation, such as visible light. The ML—which may include silicon in some embodiments—may serve a function similar to an amplifier and is configured to control a multiplication factor and a breakdown voltage of the APD 100. The charging layer is implemented to divide or otherwise separate the electric fields of the optical absorption layer and the ML. For example, the charging layer may include a silicon material that is doped with a P-type dopant, but the dopant concentration level of the charging layer is substantially less than the dopant concentration level of the P+ contact.

The graph 110 in FIG. 1B also includes an X-axis spanning a horizontal direction and a Z-axis spanning a vertical direction. The locations along the X-axis of FIG. 1B corresponds to the locations along the X-axis of FIG. 1A. Meanwhile, the Z-axis represents the intensity of the electric field. In more detail, the graph 110 includes a plot 120 that corresponds to the electric field of the APD 100 at different regions of the APD 100. For example, the electric field of the ML is the strongest, which is reflected by the fact that the plot 120 has the greatest height at locations corresponding to the ML. The electric field of the optical absorption layer is substantially weaker, which is reflected by the fact that the plot 120 has a substantially lower height at locations corresponding to the optical absorption layer. Since the charging layer separates the ML and the optical absorption layer, the electric field of the charging layer varies, as it is stronger near the ML and ramps down toward the optical absorption layer. One of the inventive aspects of the present pertains to the formation of the charging layer, such that it can achieve a relatively narrow width, while being abutted directly to the optical absorption layer, where an interface between the charging layer and the optical absorption layer has a substantially vertical doping profile.

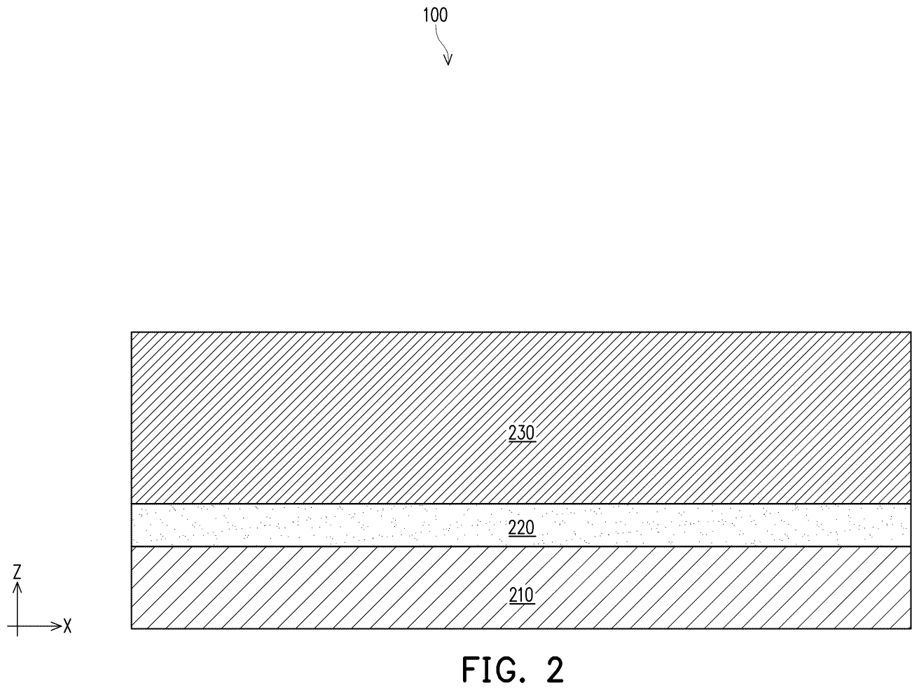

The fabrication process flow of the APD 100 will now be discussed below in more detail with reference to FIGS. 2-34, which are cross-sectional sides views of the APD 100 at different stages of fabrication. The cross-sectional views are taken along a plane defined by a horizontal X-direction (or X-axis) and a vertical Z-direction (or Z-axis).

Referring now to FIG. 2, the fabrication of the APD 100 includes providing a substrate 210 as a part of a wafer. The substrate 210 may include a semiconductor material. For example, the substrate 210 may include silicon as the semiconductor material. An insulator layer 220 is formed over the substrate 210. In some embodiments, the insulator layer 220 may include silicon oxide (SiO₂). Another semiconductor layer 230 is formed over the insulator layer 220. For example, the semiconductor layer 230 may also include silicon with a <100> lattice direction or silicon with a <111> lattice direction. In this manner, a silicon-on-insulator (SOI) structure is formed by the substrate 210, the insulator layer 220, and the semiconductor layer 230. The SOI structure may offer reduced parasitic capacitance, which helps to improve device performance.

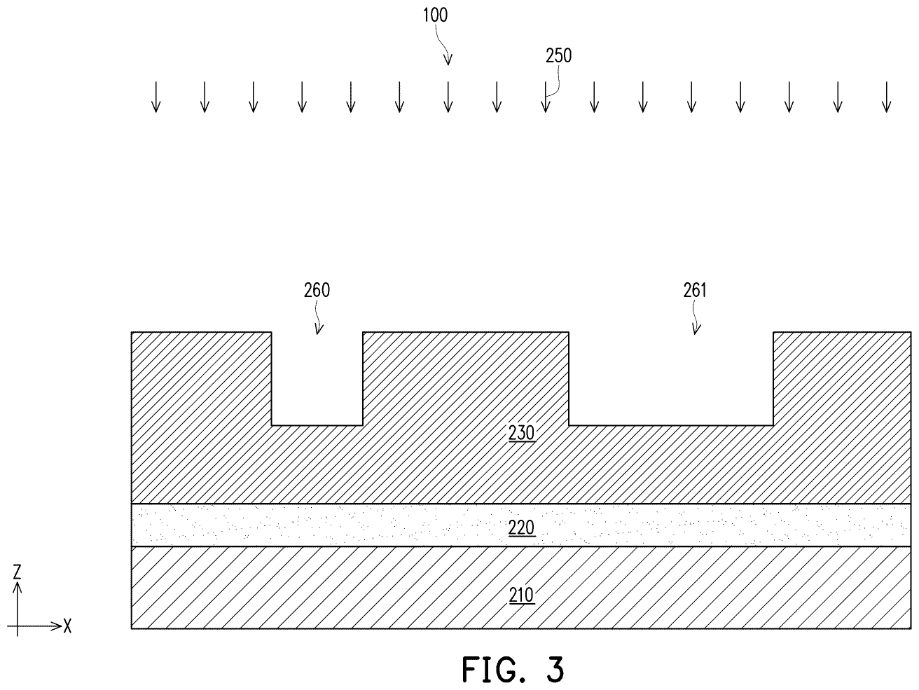

Referring now to FIG. 3, an etching process 250 is performed to the APD 100 to form a plurality of openings in the semiconductor layer 230. In some embodiments, the etching process 250 includes a lithography process, which may include one or more photoresist spin coating processes, photoresist exposure processes, post-exposure baking processes, photoresist developing processes, etc. (not necessarily performed in that order). The lithography process may form a patterned photoresist mask (not specifically illustrated herein for reasons of simplicity) over the semiconductor layer 230. The etching process 250 may include one or more dry etching processes or wet etching processes to partially etch away the semiconductor layer 230. The patterned photoresist mask serves as a protective mask to prevent the portions of the semiconductor layer 230 therebelow from being etched during the etching process 250. As a result of the etching process 250 being performed, openings 260 and 261 are formed in the semiconductor layer 230. The openings 260 and 261 each extend downwardly partially through the semiconductor layer 230 in the Z-direction. The patterned photoresist mask may be removed after the formation of the openings 260 and 261, for example, by a photoresist ashing process or a photoresist stripping process.

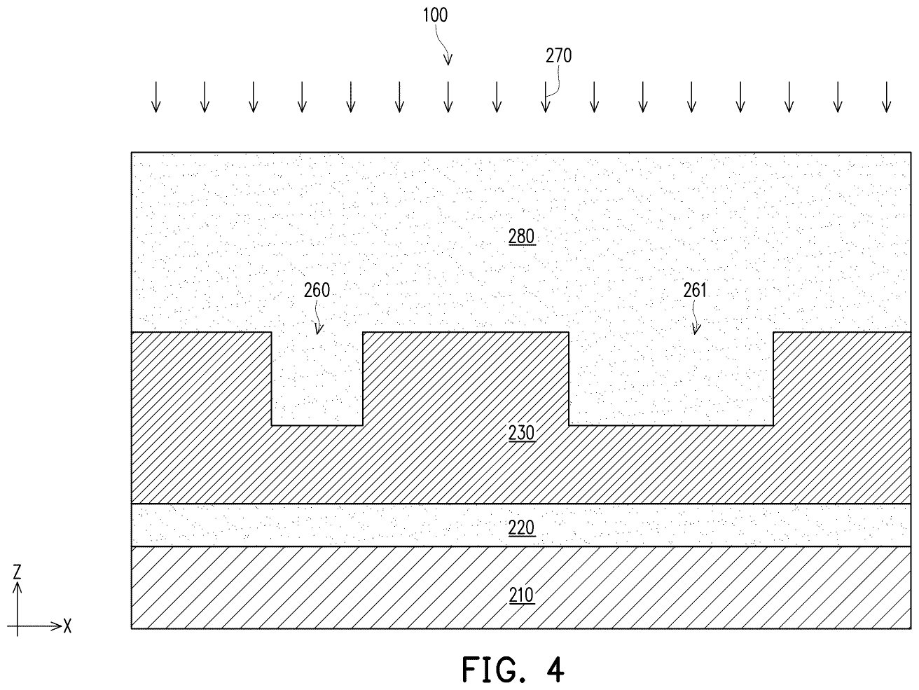

Referring now to FIG. 4, a deposition process 270 is performed to the APD 100 to form a dielectric layer 280. The deposition process 270 may include a physical vapor deposition (PVD), a chemical vapor deposition (CVD), an atomic layer deposition (ALD) process, or combinations thereof. In some embodiments, the dielectric layer 280 includes silicon oxide. The dielectric layer 280 is deposited over the semiconductor layer 230 and fills the openings 260 and 261.

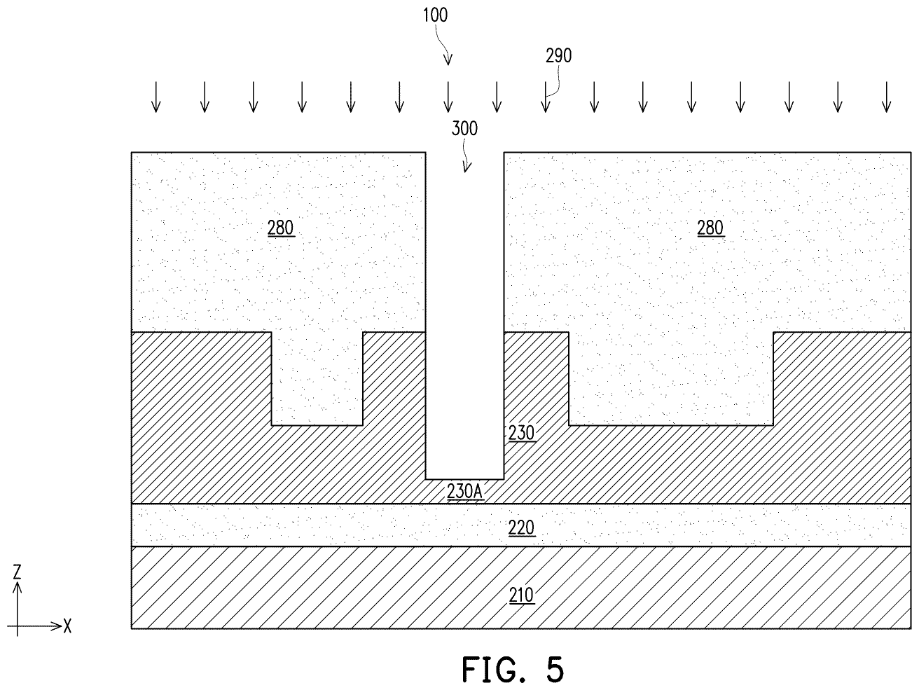

Referring now to FIG. 5, an etching process 290 is performed to the APD 100 to form an opening 300. In some embodiments, the etching process 290 include a dry etching process, a wet etching process, or combinations thereof. It is understood that a lithography process may also be performed to form a patterned photoresist mask, which may be used as a protective mask during the performance of the etching process 290. As a result of the etching process 290, the opening 300 extends downwardly in the Z-direction through the dielectric layer 280 and partially through the semiconductor layer 230. Note that the etching process 290 is specifically configured to ensure that a segment 230A of the semiconductor layer 230 remains after the etching process 290 has been performed. In other words, the segment 230A of the semiconductor layer 230 is exposed by the opening 300.

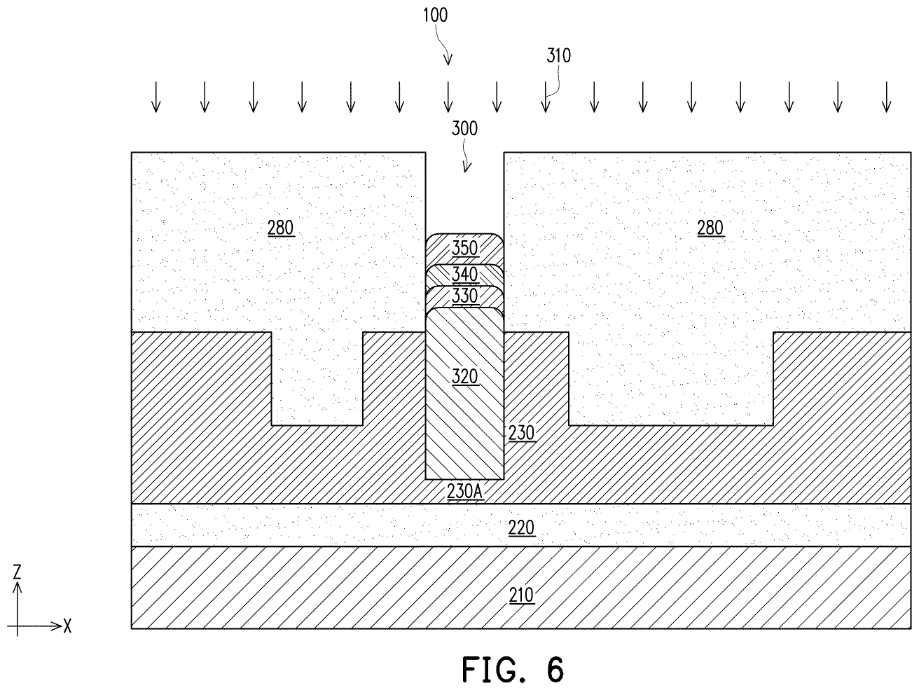

Referring now to FIG. 6, a selective growth process 310 is performed to the APD 100 to form an optical absorption layer 320 in the opening 300. In more detail, the segment 230A serves as a seed layer during the selective growth process 310. The selective growth process 310 may then utilize a deposition technique (such as CVD) to grow a semiconductor material on the segment 230A. In some embodiments, the semiconductor material grown on the segment 230A may include germanium. This germanium material may be referred to as the optical absorption layer 320. The optical absorption layer 320 is selectively grown on the segment 230A (which contains silicon in this embodiment), but not on the upper surfaces of the dielectric layer 280 (which contains silicon oxide in this embodiment). As such, the optical absorption layer 320 is grown within, but not outside of, the opening 300. Note that in this embodiment illustrated in FIG. 6, the thickness (or height) of the optical absorption layer 320 is configured such that an uppermost surface of the optical absorption layer 320 has a more vertically elevated position than an uppermost surface of the semiconductor layer 230. However, this may not be the case in alternative embodiments.

It is also understood that although germanium is used as an example material for the optical absorption layer 320, it is not intended to be limiting unless otherwise claimed. For example, a silicon germanium (SiₓGe₁₋ₓ, where x is between 0 and 1) compound may also be used to implement the optical absorption layer 320 in some embodiments, depending on the operating wavelength (e.g., varying from about 1100 nm and about 2000 nm) of the APD 100.

After the formation of the optical absorption layer 320 in the opening 300, a plurality of deposition processes (e.g., CVD, PVD, ALD, or combinations thereof) may be performed to form additional layers, such as layers 330, 340, and 350, over the optical absorption layer 320 in the opening 300. For example, the layer 330 may include a semiconductor material such as silicon, the layer 340 may include a dielectric material such as silicon oxide, and the layer 350 may include another semiconductor material such as polysilicon. The layers 330-350 may have substantially smaller thicknesses compared to the optical absorption layer 320. In the illustrated embodiment, the combination of the optical absorption layer 320 and the layers 330-350 still do not fill the opening 300 completely. In other words, an uppermost surface of the layer 350 has a less vertically elevated position than an uppermost surface of the dielectric layer 280. The layers 330-350 may be used collectively to serve as a mask structure in later processes, as will be discussed in greater detail below.

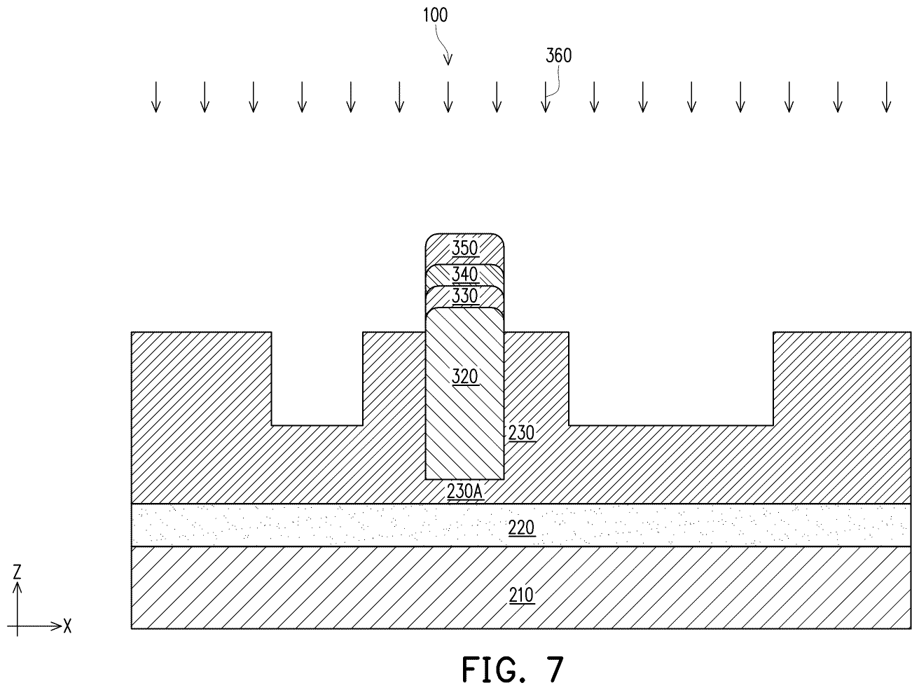

Referring now to FIG. 7, a dielectric removal process 360 is performed to the APD 100 to remove the dielectric layer 280. The dielectric removal process 360 is configured to remove the dielectric layer 280 without substantially impacting the semiconductor layer 230, the optical absorption layer 320, or the layers 330-350. For example, the dielectric removal process 360 may include one or more etching processes configured with a sufficiently high etching selectivity between the dielectric layer 280 and the other layers 230 and 320-350. In some embodiments, the etching processes of the dielectric removal process 360 may be configured such that the dielectric layer 280 may be etched away at a rate that is more than five times or more than ten times faster than the other layers 230 and 320-350. Consequently, it is possible for the dielectric layer 280 to be removed while the other layers 230 and 320-350 substantially remain.

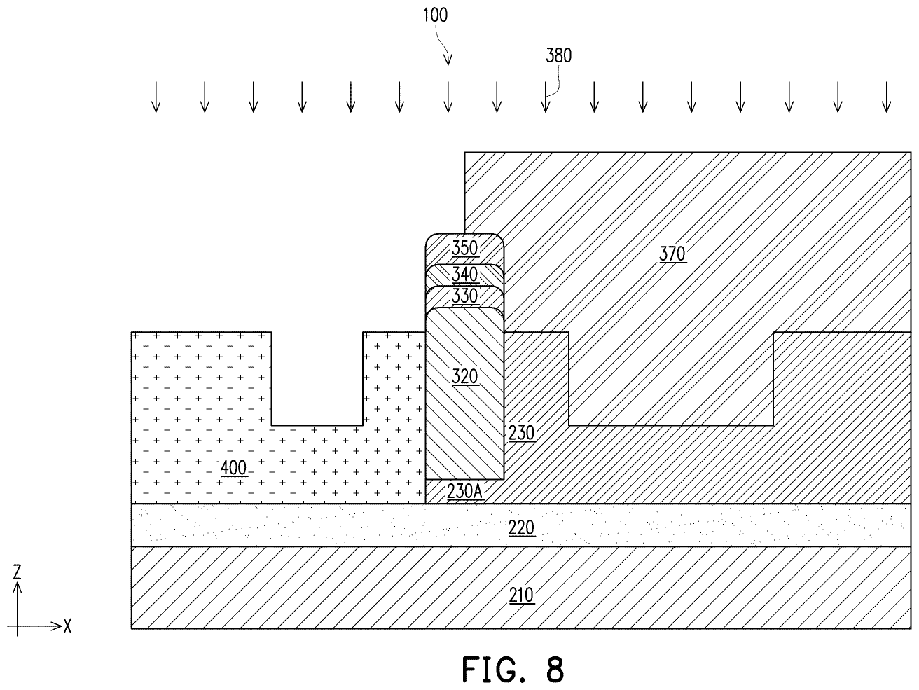

Referring now to FIG. 8, a patterned photoresist mask 370 is formed over a portion of the APD 100. For example, the patterned photoresist mask 370 is formed to cover a “right side” of the APD 100, including over the portion of the semiconductor layer 230 to the “right side” of the optical absorption layer 320, as well as over a “right side” portion of the layer 350. Thereafter, a doping process 380 is performed to transform the portion of the semiconductor layer 230 to the “left side” of the optical absorption layer 320 into a P+ contact 400. For example, the doping process 380 may implant a P-type dopant material into the exposed portion of the semiconductor layer 230 (i.e., the portion of the semiconductor layer 230 to the “left side” of the optical absorption layer 320). The patterned photoresist mask 370 protects the various layers there below (including the semiconductor layer 230 to the “right side” of the optical absorption layer 320) from being implanted by the dopant material. Similarly, the layers 330-350 may also serve as a mask structure to protect the optical absorption layer 320 below from being implanted by the dopant material. As a result, the semiconductor layer 230 to the “left side” of the optical absorption layer 320 is transformed into the P+ contact 400, while the semiconductor layer 230 to the “right side” of the optical absorption layer 320 still remains substantially undoped at this stage of fabrication. It is understood that the P+ contact 400 corresponds to the P+ contact discussed above with reference to FIG. 1.

Note that as an inherent result of the unique fabrication processes discussed above, the optical absorption layer 320 is formed directly abutting the P+ contact 400. For example, the etching of the opening 300 (see FIG. 5) and the subsequent selective growth of the optical absorption layer 320 in the opening 300 allows the optical absorption layer 320 to be directly abutted to the semiconductor layer 230 to its “left side”. Thereafter, the doping process 380 transforms the portion of the semiconductor layer 230 directly abutted to the “left side” of the optical absorption layer 320 into the P+ contact 400, while the layers 330-350 protect the optical absorption layer 320 from being doped. As such, the optical absorption layer 320 is formed to be directly abutted to the P+ contact 400 through self-alignment.

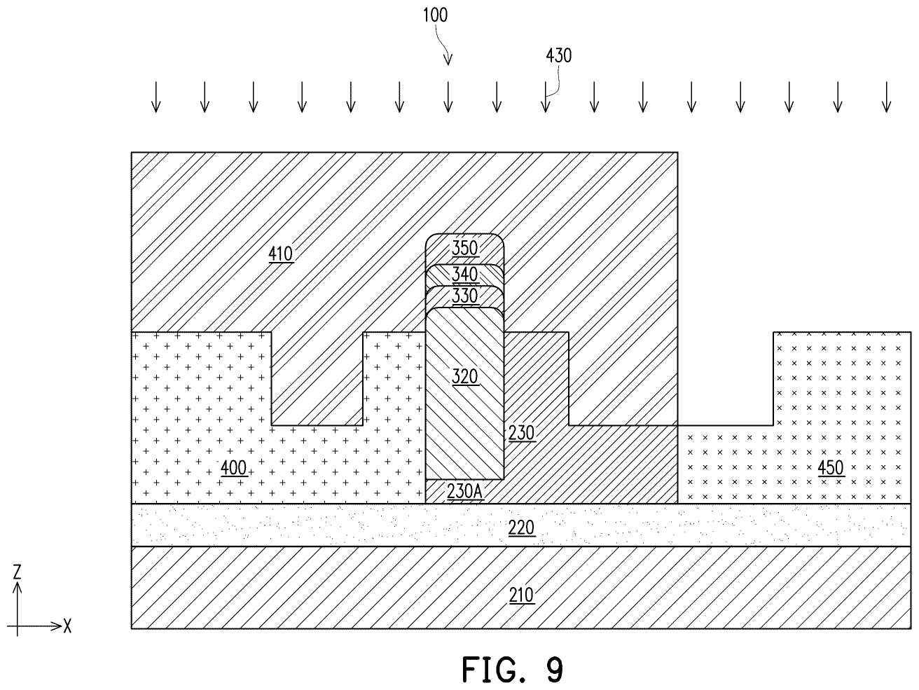

Referring now to FIG. 9, the patterned photoresist mask 370 is removed, for example, through a photoresist ashing or photoresist stripping process. Thereafter, another patterned photoresist mask 410 is formed over a portion of the APD 100. For example, the patterned photoresist mask 410 is formed to cover a “left side” of the APD 100, including over the P+ contact 400, over a portion of the optical absorption layer 320 and the layers 330-350 above, and over a portion of the semiconductor layer 230 to the “right side” of the optical absorption layer 320.

Thereafter, a doping process 430 is performed to transform the portion of the semiconductor layer 230 not covered by the patterned photoresist mask 410 into an N+ contact 450. For example, the doping process 430 may implant an N-type dopant material into the exposed portion of the semiconductor layer 230. The patterned photoresist mask 410 protects the various layers there below from being implanted by the dopant material. As a result, the exposed portion of the semiconductor layer 230 is transformed into the N+ contact 450, while the portion of the semiconductor layer 230 to the “right side” of the optical absorption layer 320 and covered by the patterned photoresist mask 410 still remains substantially undoped at this stage of fabrication. It is understood that the N+ contact 450 corresponds to the N+ contact discussed above with reference to FIG. 1.

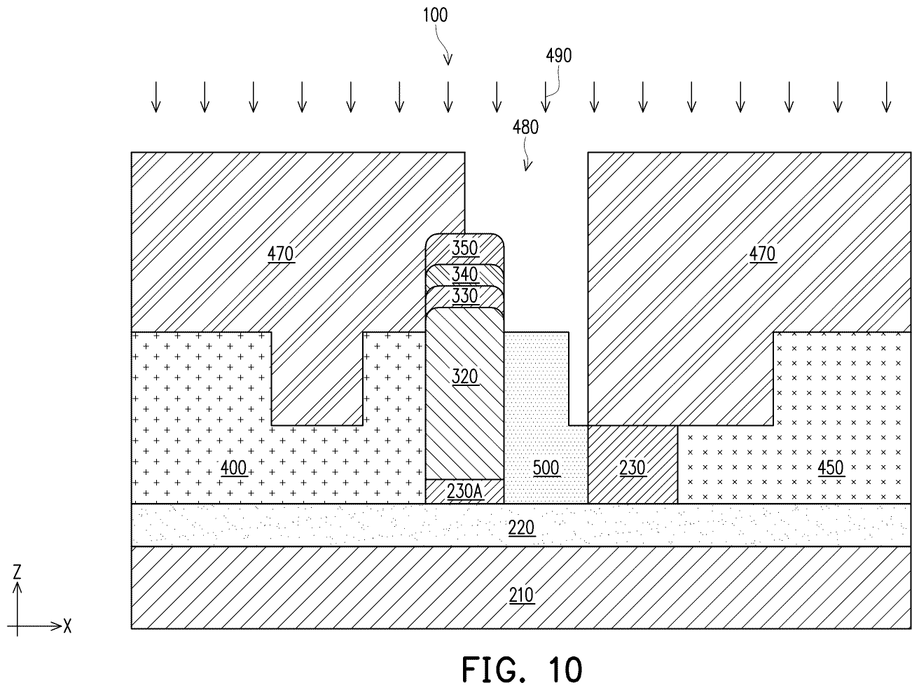

Referring now to FIG. 10, the patterned photoresist mask 410 is removed, for example, through a photoresist ashing or photoresist stripping process. Thereafter, another patterned photoresist mask 470 is formed over portions of the APD 100. For example, the patterned photoresist mask 470 is formed to define an opening 480 that exposes a portion of the semiconductor layer 230 directly abutting a “right side” of the optical absorption layer 320. The opening 480 also exposes a portion of the layer 350. The remaining components of the APD 100 are covered up by the patterned photoresist mask 470.

Thereafter, a doping process 490 is performed to transform the portion of the semiconductor layer 230 not covered by the patterned photoresist mask 470 into a charging layer 500. For example, the doping process 490 may implant a P-type dopant material into the exposed portion of the semiconductor layer 230. The patterned photoresist mask 470 and the layers 330-350 protect the various layers there below from being implanted by the dopant material. As a result, the portion of the semiconductor layer 230 exposed by the opening 480 is transformed into the charging layer 500, while the portion of the semiconductor layer 230 covered by the patterned photoresist mask 470 still remains substantially undoped at this stage of fabrication. The optical absorption layer 320 also remains undoped due to the protection offered by the layers 330-350. It is understood that the charging layer 500 corresponds to the charging layer discussed above with reference to FIG. 1.

It is also understood that the dose of the P-type dopant material of the doping process 490 is substantially lower than the dose of the P-type dopant material of the doping process 380 (see FIG. 8) used to form the P+ contact 400. As such, the resulting charging layer 500 formed by the doping process 490 is substantially less doped (e.g., having a substantially lower dopant concentration level) compared to the P+ contact 400. It is further understood that the dopant concentration levels in the various doped regions of the APD 100 may be adjusted according to a breakdown condition (e.g., to avoid breakdown) and/or to generate the desired electric field profile.

Note that as another inherent result of the unique fabrication processes discussed above, the charging layer 500 is formed directly abutting the optical absorption layer 320. For example, the etching of the opening 300 (see FIG. 5) and the subsequent selective growth of the optical absorption layer 320 in the opening 300 allows the optical absorption layer 320 to be directly abutted to the portion of the semiconductor layer 230 to its “right side”. Thereafter, the doping process 490 transforms the portion of the semiconductor layer 230 directly abutted to the “right side” of the optical absorption layer 320 into the charging layer 500, while the layers 330-350 protect the optical absorption layer 320 from being doped. As such, the charging layer 500 is formed to be directly abutted to the optical absorption layer 320 through self-alignment.

It is also understood that a width (e.g., horizontal dimension in the X-direction) of the charging layer 500 may be flexibly configured. For example, the width of the charging layer 500 is determined at least in part by a width of the opening 480, which is defined by the patterned photoresist mask 470. In embodiments where the width of the charging layer 500 is desired to be a bit smaller, the patterned photoresist mask 470 may be formed to define a narrower opening, which would expose a smaller amount of the semiconductor layer 230 therebelow, and this allows the resulting charging layer 500 (formed by the doping process 490) to have a narrower width. Conversely, in embodiments where the width of the charging layer 500 is desired to be a bit larger, the patterned photoresist mask 470 may be formed to define a wider opening, which would expose a greater amount of the semiconductor layer 230 therebelow, and this allows the resulting charging layer 500 (formed by the doping process 490) to have a wider width.

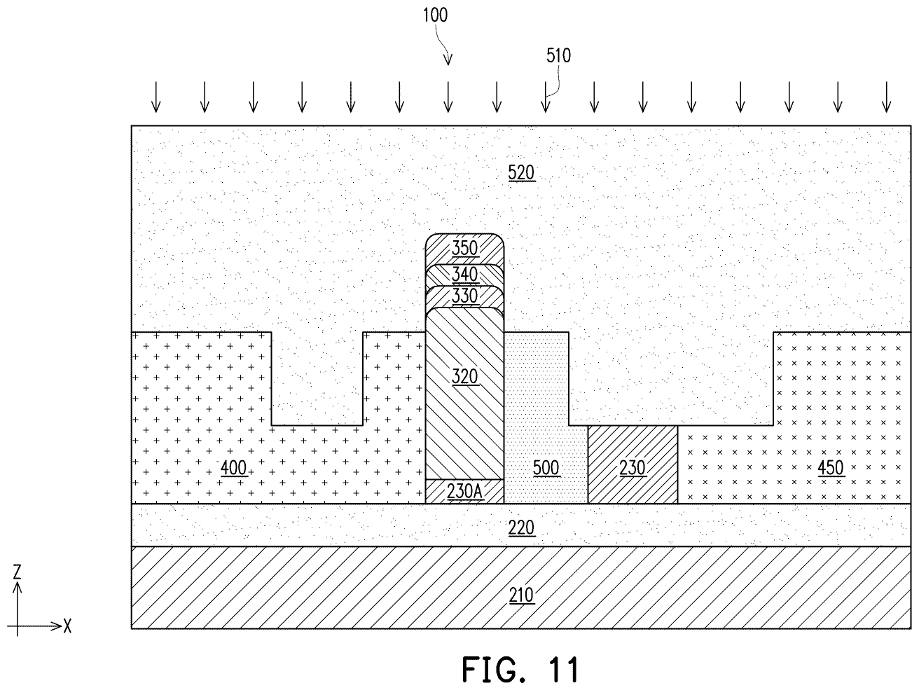

Referring now to FIG. 11, the patterned photoresist mask 470 is removed, for example, through a photoresist ashing or photoresist stripping process. Thereafter, a deposition process 510 is performed to form a passivation layer 520 over the other components of the APD 100. For example, the deposition process 510 may include a CVD process, a PVD process, an ALD process, or combinations thereof, in order to deposit a dielectric material as the passivation layer. In some embodiments, the deposited dielectric material may include a silicon nitride material or a silicon oxide material. The resulting passivation layer 520 protects the components of the APD 100 therebelow from contaminant particles and/or moisture.

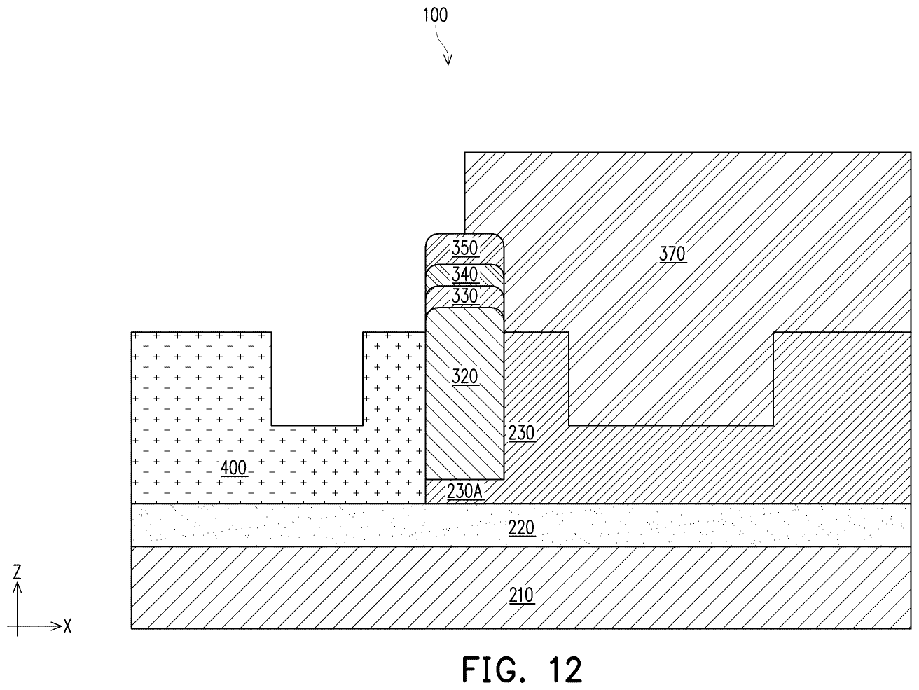

FIGS. 2-11 illustrate a process flow according to a first embodiment of the present disclosure. FIGS. 12-18 illustrate a process flow according to a second embodiment of the present disclosure. For reasons of consistency and clarity, similar components in the first embodiment and the second embodiment will be labeled the same.

Referring now to FIG. 12, the APD 100 is at the same stage of fabrication discussed above with reference to FIG. 8. That is, the APD 100 has undergone the processing steps of FIGS. 2-8 to facilitate the formation of the optical absorption layer 320, the layers 330-350 above the optical absorption layer 320, and the P+ contact 400. Since these processes are substantially the same in both the first embodiment and the second embodiment, the discussions for these processes are not repeated herein for reasons of simplicity.

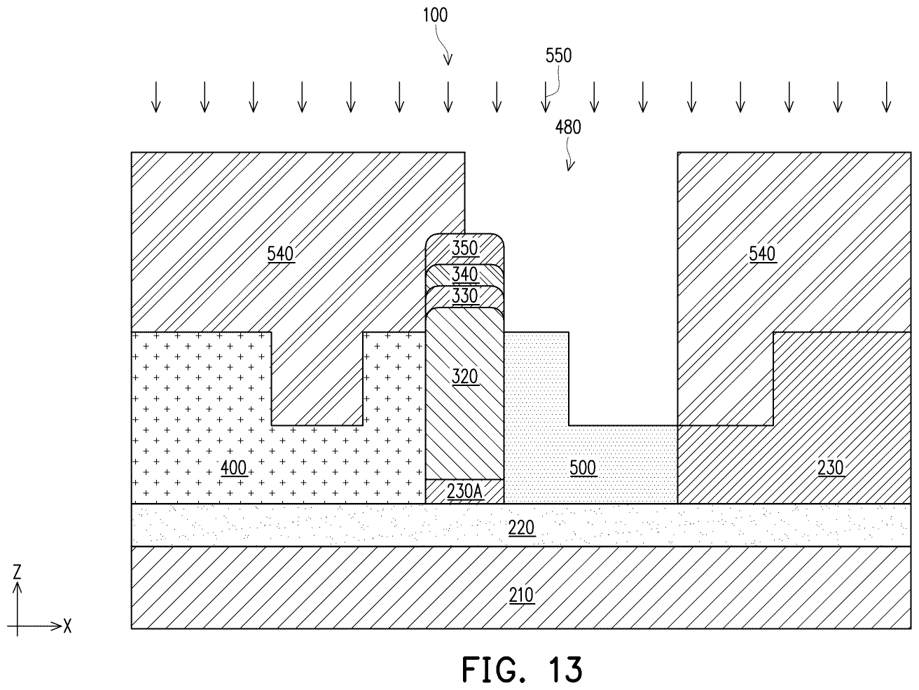

Referring now to FIG. 13, the patterned photoresist mask 370 is removed, for example, through a photoresist ashing or photoresist stripping process. Thereafter, another patterned photoresist mask 540 is formed over a portion of the APD 100. For example, the patterned photoresist mask 540 is formed to cover a “left side” of the APD 100, including over the P+ contact 400, over a portion of the optical absorption layer 320 and the layers 330-350 above, and over a portion of the semiconductor layer 230 to the “right side” of the optical absorption layer 320. The patterned photoresist mask 540 is formed to define the opening 480 that exposes a portion of the semiconductor layer 230 directly abutting a “right side” of the optical absorption layer 320. The opening 480 also exposes a portion of the layer 350. The remaining components of the APD 100 are covered up by the patterned photoresist mask 540.

Thereafter, a doping process 550 is performed to transform the portion of the semiconductor layer 230 not covered by the patterned photoresist mask 540 into the charging layer 500. For example, the doping process 550 may implant a P-type dopant material into the exposed portion of the semiconductor layer 230. The patterned photoresist mask 540 and the layers 330-350 protect the various layers there below from being implanted by the dopant material. As a result, the portion of the semiconductor layer 230 exposed by the opening 480 is transformed into the charging layer 500, while the portion of the semiconductor layer 230 covered by the patterned photoresist mask 540 still remains substantially undoped at this stage of fabrication. The optical absorption layer 320 also remains undoped due to the protection offered by the layers 330-350. As discussed above, the charging layer 500 is substantially less doped (e.g., having a substantially lower dopant concentration level) compared to the P+ contact 400, even though they each contain a P-type dopant.

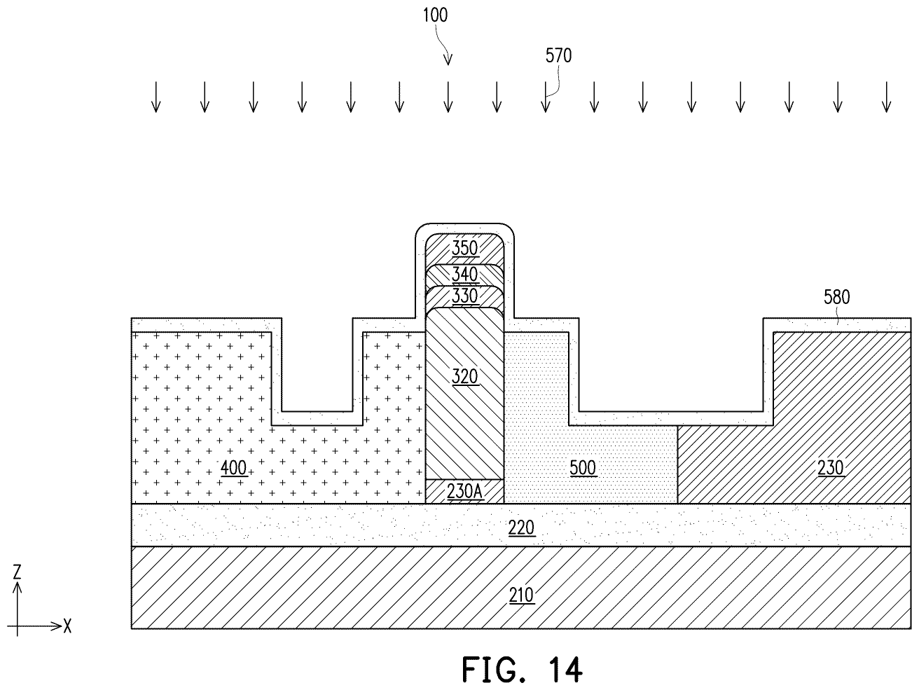

Referring now to FIG. 14, the patterned photoresist mask 540 is removed, for example, through a photoresist ashing or photoresist stripping process. Thereafter, a sputtering process 570 is performed to the APD 100 to form a spacer layer 580. In some embodiments, the sputtering process 570 forms silicon oxide as the material for the spacer layer 580. The sputtering process 570 is performed such that the spacer layer 580 covers the exposed upper surfaces and side surfaces of the APD 100, including the upper surfaces and the side surfaces of the exposed portions of the optical absorption layer 320 and the layers 330-350. In some embodiments, the sputtering process 570 is configured such that the spacer layer 580 has a substantially uniform thickness. It is understood that this thickness of the spacer layer 580 may be used to control a width of spacers to be formed in a subsequent process discussed below.

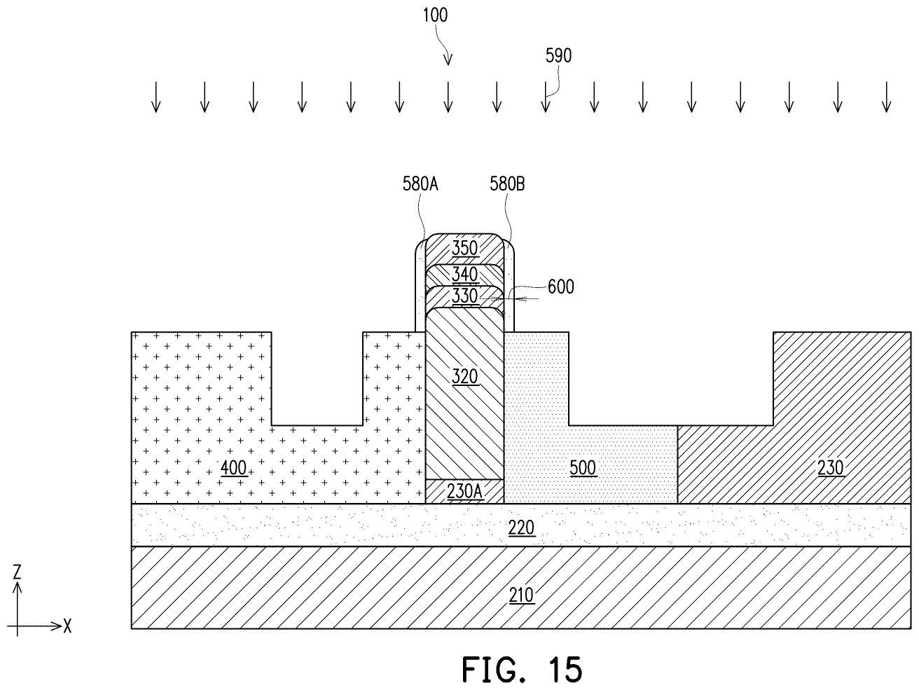

Referring now to FIG. 15, one or more etching processes 590 are performed to transform the spacer layer 580 into spacers. In more detail, the one or more etching processes 590 may include one or more isotropic etching processes (e.g., wet etching) to etch away portions of the spacer layer 580. The isotropic etching processes are configured to have a sufficiently high etching selectivity between the spacer layer 580 and the rest of the components of the APD 100 (e.g., the P+ contact 400, the layer 350, the charging layer 500, and the semiconductor layer 230). As such, the etching of the spacer layer 580 does not substantially affect the rest of the components of the APD 100. The portions of the spacer layer 580 disposed on the exposed side surfaces of the optical absorption layer 320 and the layers 330-350 are substantially taller than the portions of the spacer layer 580 disposed elsewhere on the APD 100. As a result, a significant portion of the spacer layer 580 disposed on the exposed side surfaces of the optical absorption layer 320 and the layers 330-350 will remain after the etching processes 590 have been performed. These remaining portions of the spacer layer 580 are hereinafter labeled as spacers 580A and 580B. The spacers 580A and 580B may each have a width 600 (e.g., a horizontal dimension measured in the X-direction). Again, the value of the width 600 is determined by the thickness of the spacer layer 580 when it was formed by the sputtering process 570 discussed above with reference to FIG. 14.

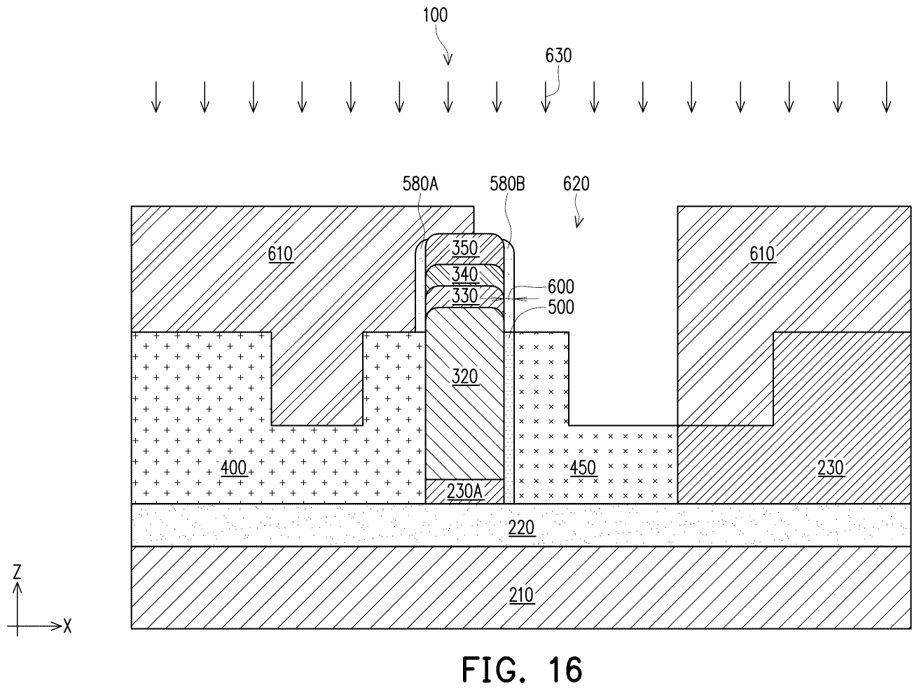

Referring now to FIG. 16, a patterned photoresist mask 610 is formed over a portion of the APD 100. For example, the patterned photoresist mask 610 is formed to cover a “left side” of the APD 100, including over the P+ contact 400, over a portion of the optical absorption layer 320 and the layers 330-350 above, and over the semiconductor layer 230. The patterned photoresist mask 610 is formed to define the opening 620 that exposes the charging layer 500, as well as a portion of the layer 350 and the spacer 580B. Thereafter, a doping process 630 is performed to transform the exposed portion of the charging layer 500 into the N+ contact 450. For example, the doping process 430 may implant an N-type dopant material into the exposed portion of the charging layer 500. The patterned photoresist mask 610 protects the various layers there below from being implanted by the dopant material. The spacer 580B also protects a portion of the charging layer 500 therebelow from being implanted by the dopant material.

As a result of the doping process 630, the exposed portion of the charging layer 500 is transformed into the N+ contact 450, while the portion of the semiconductor layer 230 covered by the patterned photoresist mask 610 still remains substantially undoped at this stage of fabrication. The remaining portion of the charging layer 500 under the spacer 580B also is substantially unaffected by the doping process 630. In other words, the remaining portion of the charging layer 500 is still lightly P-doped at this stage of fabrication. In this manner, the charging layer 500 herein achieves a substantially elongated and narrow (e.g., having the width 600) profile and directly abuts the optical absorption layer 320. Such a physical characteristic of the charging layer 500 is an inherent result of the unique fabrication process flow of the present disclosure being performed. For example, the charging layer 500 herein is formed in a self-aligned manner, such that its horizontal location is defined by the spacer 580B. Since the spacer 580B is formed to directly abut the optical absorption layer 320, the charging layer 500 naturally inherits the horizontal location of the spacer 580B and therefore also directly abuts the optical absorption layer 320. In addition, since the charging layer 500 is defined by the spacer 580B, the charging layer 500 also substantially inherits the width 600 of the spacer 580B. In this manner, a lightly P-doped narrow charging layer 500 having a substantially vertical shape is formed directly adjacent to the optical absorption layer 320, which is one of the unique physical characteristics of the present disclosure.

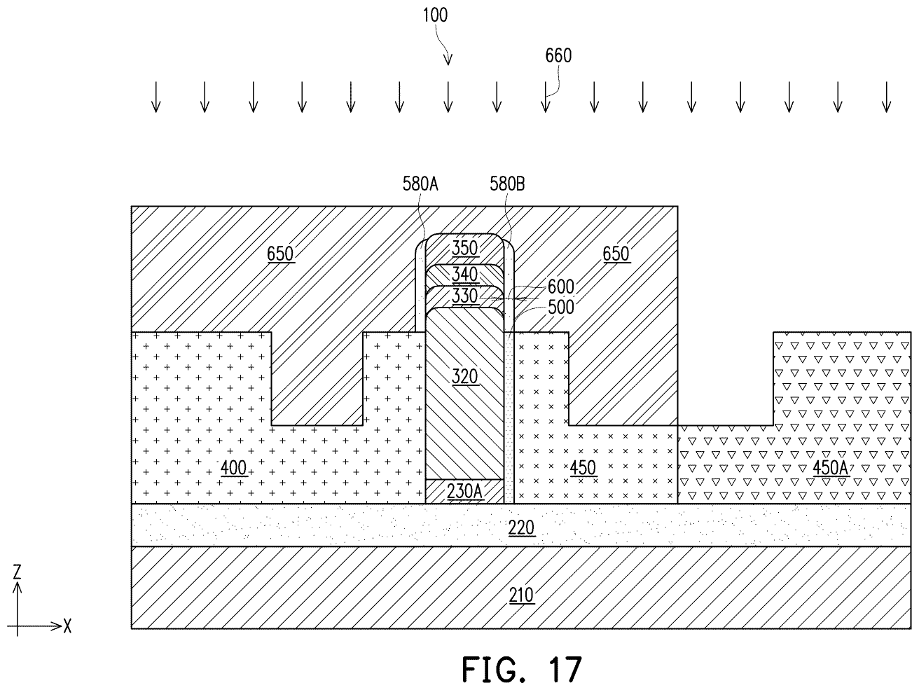

Referring now to FIG. 17, the patterned photoresist mask 610 is removed, for example, through a photoresist ashing or photoresist stripping process. Thereafter, another patterned photoresist mask 650 is formed. The patterned photoresist mask 650 exposes the semiconductor layer 230 (previously covered by the patterned photoresist mask 610, see FIG. 16) but covers a rest of the APD 100. Thereafter, a doping process 660 is performed. The doping process 660 may implant an N-type dopant material into the semiconductor layer 230. The patterned photoresist mask 650 protects the various layers there below from being implanted by the dopant material. As a result, the semiconductor layer 230 is transformed into an N++ contact 450A. It is understood that the doping process 660 may use a greater dosage for the N-type of dopant than the doping process 630. As a result, the dopant concentration level of the N-type dopant in the N++ contact 450A is greater than the dopant concentration level of the N-type dopant in the N+ contact 450. It is understood that the N+ contact 450 and the N++ contact 450A may collectively correspond to the N+ contact discussed above with reference to FIG. 1.

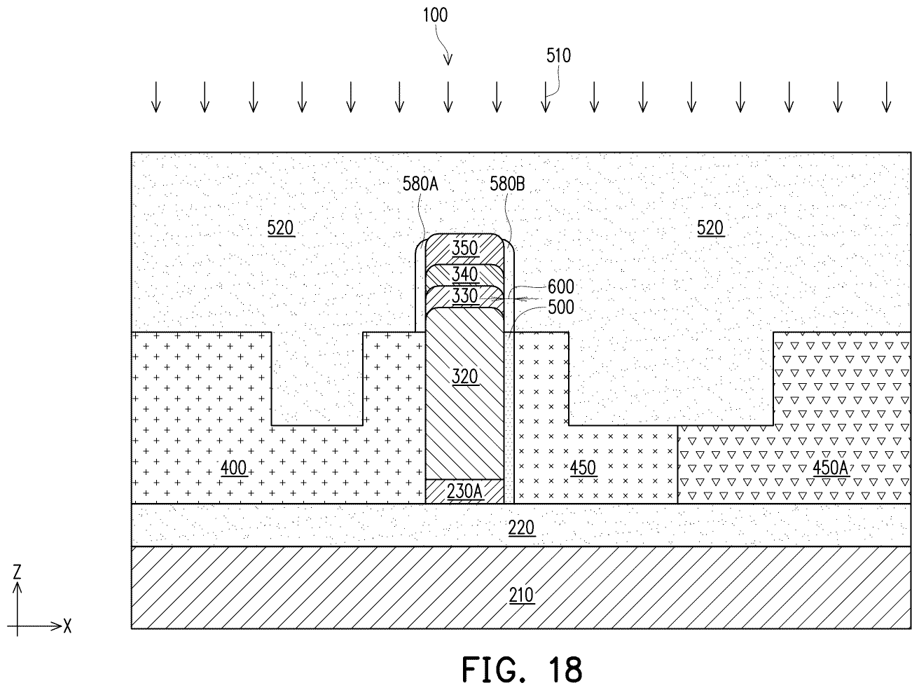

Referring now to FIG. 18, the patterned photoresist mask 650 is removed, for example, through a photoresist ashing or photoresist stripping process. Thereafter, the deposition process 510 discussed above is performed to form the passivation layer 520 over the other components of the APD 100. For example, the deposition process 510 may include a CVD process, a PVD process, an ALD process, or combinations thereof, in order to deposit a dielectric material as the passivation layer. In some embodiments, the deposited dielectric material may include a silicon nitride material or a silicon oxide material. The resulting passivation layer 520 protects the components of the APD 100 therebelow from contaminant particles and/or moisture.

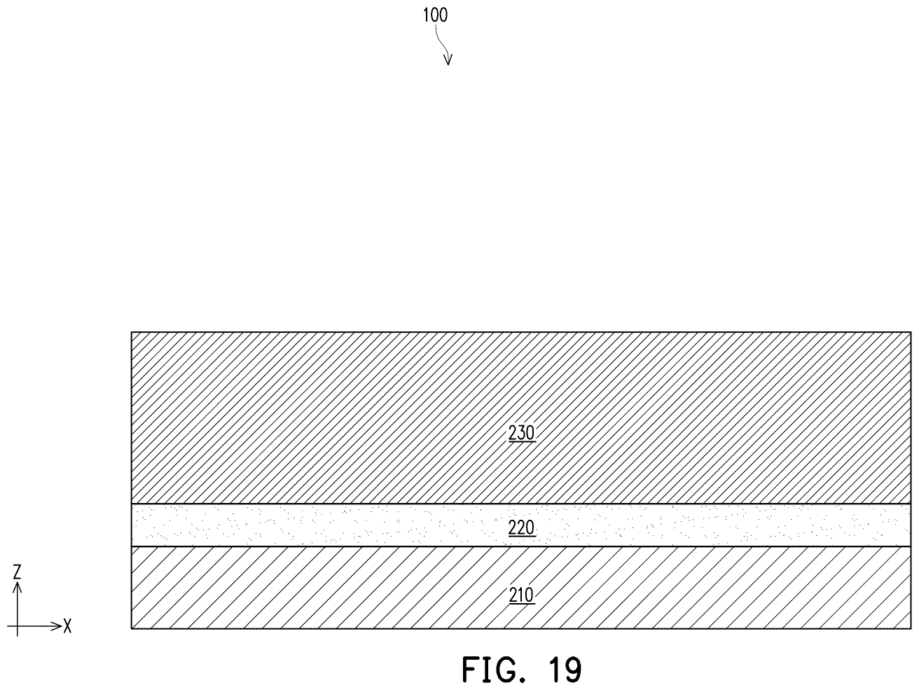

FIGS. 2-11 and FIGS. 12-18 illustrate process flows according to the first embodiment and the second embodiment of the present disclosure, where the etching of the semiconductor layer 230 (e.g., the etching process 290 of FIG. 5) is performed before the various doping processes discussed above are performed to form the P+ contact 400 and the N+ contact 450. In other words, the first embodiment and the second embodiment discussed above with reference to FIGS. 2-18, the doping processes used to form the P+ contact 400 and the N+ contact 450 are performed after the selective growth process to form the optical absorption layer 320. However, such a process order is not limiting unless otherwise claimed. For example, FIGS. 19-33 (to be discussed below in more detail) illustrate a process flow according to a third embodiment of the present disclosure, where doping processes used to form the N+ contact and the P+ contact are performed before the selective growth process 320 is performed to form the optical absorption layer 320. For reasons of consistency and clarity, similar components in the first embodiment, the second embodiment, and the third embodiment will be labeled the same.

Referring now to FIG. 19, the APD 100 is at the same stage of fabrication discussed above with reference to FIG. 2. That is, the APD 100 includes the substrate 210, the insulator layer 220, and the semiconductor layer 230, but no other fabrication processes have been performed to the APD 100 yet.

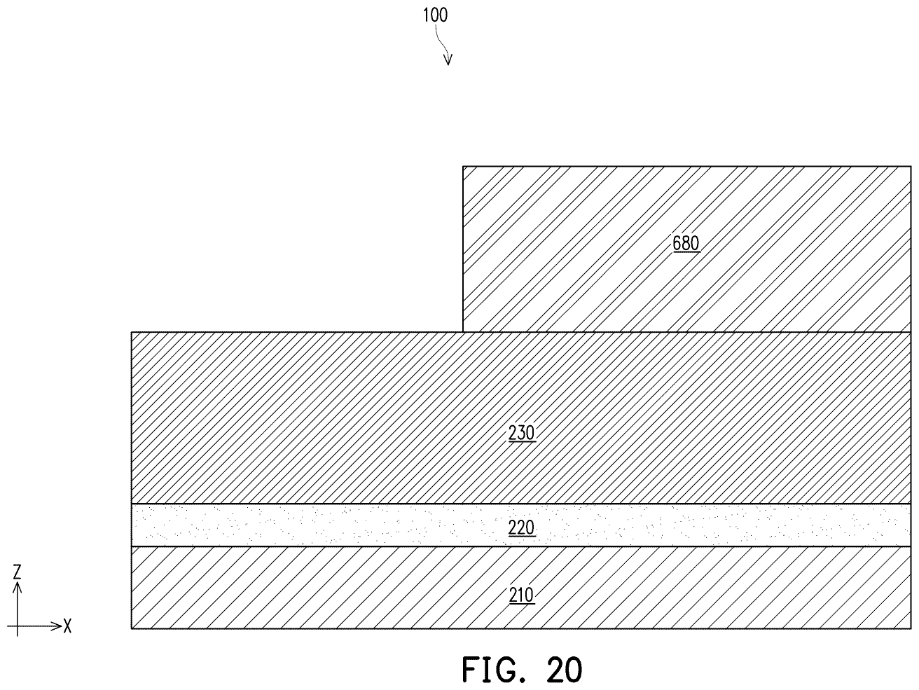

Referring now to FIG. 20, a patterned photoresist mask 680 is formed. The patterned photoresist mask 680 exposes a portion of the semiconductor layer 230 but covers a rest of the APD 100.

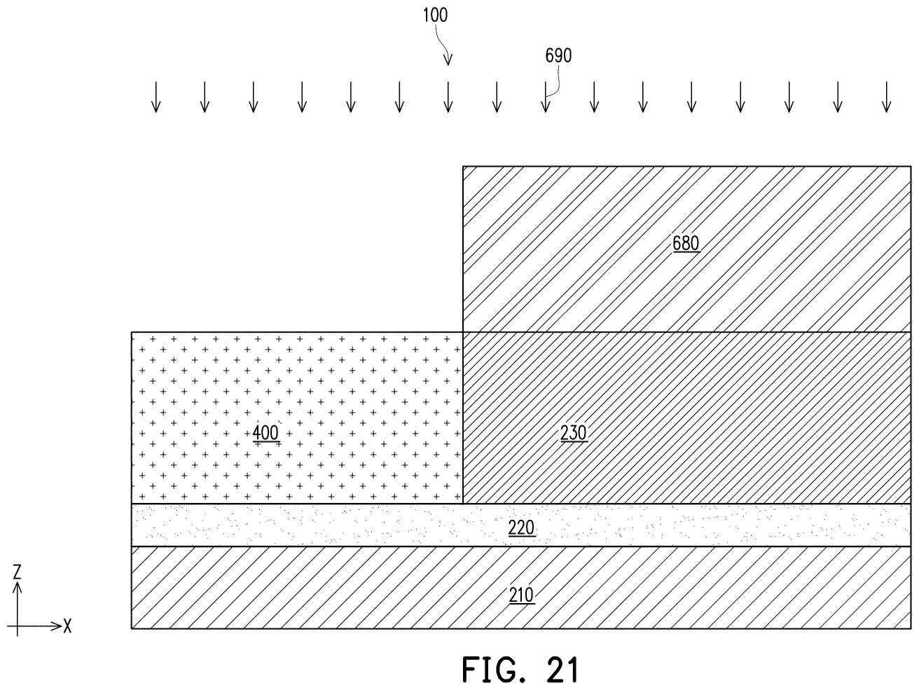

Referring now to FIG. 21, a doping process 690 is performed. The doping process 690 may implant a P-type dopant material into the semiconductor layer 230. The patterned photoresist mask 680 protects the semiconductor layer 230 therebelow from being implanted by the dopant material. As a result, the exposed portion of the semiconductor layer 230 is transformed into the P+ contact 400. It is understood that the P+ contact 400 corresponds to the P+ contact discussed above with reference to FIG. 1.

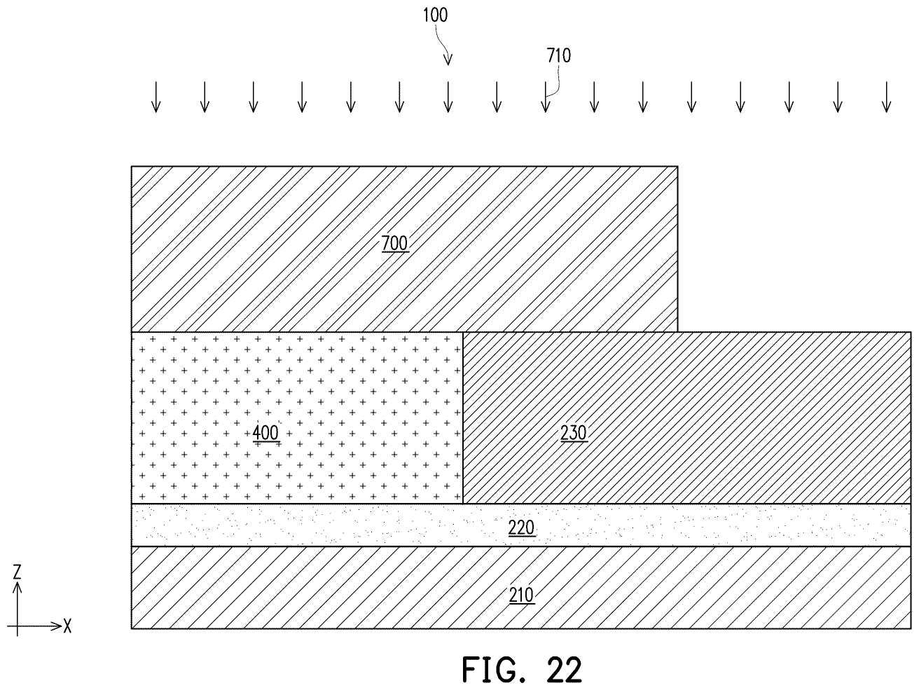

Referring now to FIG. 22, the patterned photoresist mask 680 is removed, for example, through a photoresist stripping or an ashing process. Thereafter, a patterned photoresist mask 700 is formed. The patterned photoresist mask 700 exposes a portion of the semiconductor layer 230 but covers a rest of the APD 100.

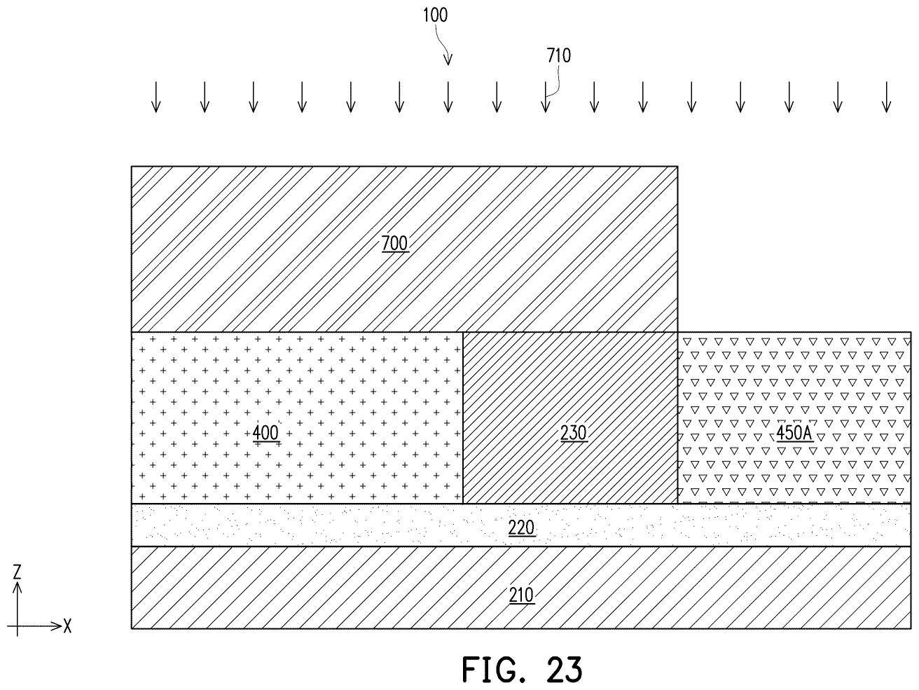

Referring now to FIG. 23, a doping process 710 is performed. The doping process 710 may implant a P-type dopant material into the exposed portion of the semiconductor layer 230. The patterned photoresist mask 700 protects the P+ contact 400 and a portion of the semiconductor layer 230 therebelow from being implanted by the dopant material. The doping process 710 is performed using a dosage similar to the doping process 660 discussed above with reference to FIG. 17. As a result, the exposed portion of the semiconductor layer 230 is transformed into the N++ contact 450A, similar to the N++ contact 450A discussed above with reference to FIG. 17.

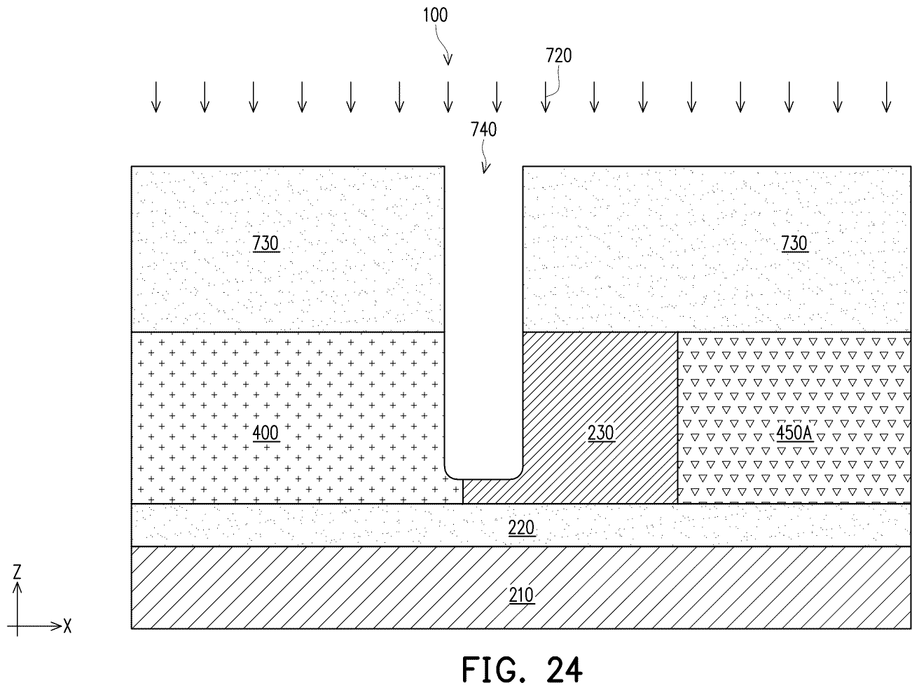

Referring now to FIG. 24, one or more etching processes 720 are performed to the APD 100. The one or more etching processes 720 are performed using a patterned mask layer 730 as a protective mask, so that the portions of the APD 100 disposed underneath the patterned mask layer 730 are not etched by the one or more etching processes 720. In some embodiments, the patterned mask layer 730 may include a dielectric material. The patterned mask layer 730 defines an opening 740, which is extended vertically downward partially through the semiconductor layer 230 and the P+ contact 400 by the one or more etching processes 720. Note that the upper and side surfaces of a portion of the semiconductor layer 230 and a portion of the P+ contact 400 remain exposed by the opening 740 after the one or more etching processes 720 have been performed.

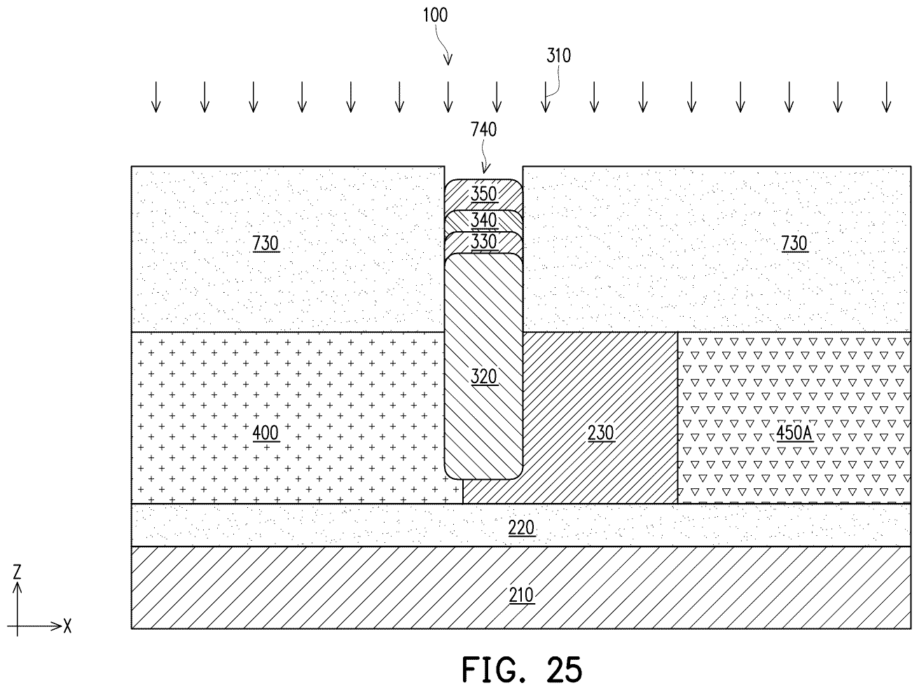

Referring now to FIG. 25, the selective growth process 310 (discussed above with reference to FIG. 6) is performed to the APD 100 to form the optical absorption layer 320 in the opening 740. As discussed above, the optical absorption layer 320 may include a germanium material. After the formation of the optical absorption layer 320 in the opening 740, the layers 330, 340, and 350 are also formed over the optical absorption layer 320 in the opening 740. For example, the layer 330 may include a semiconductor material such as silicon, the layer 340 may include a dielectric material such as silicon oxide, and the layer 350 may include another semiconductor material such as polysilicon. The layers 330-350 may have substantially smaller thicknesses compared to the optical absorption layer 320.

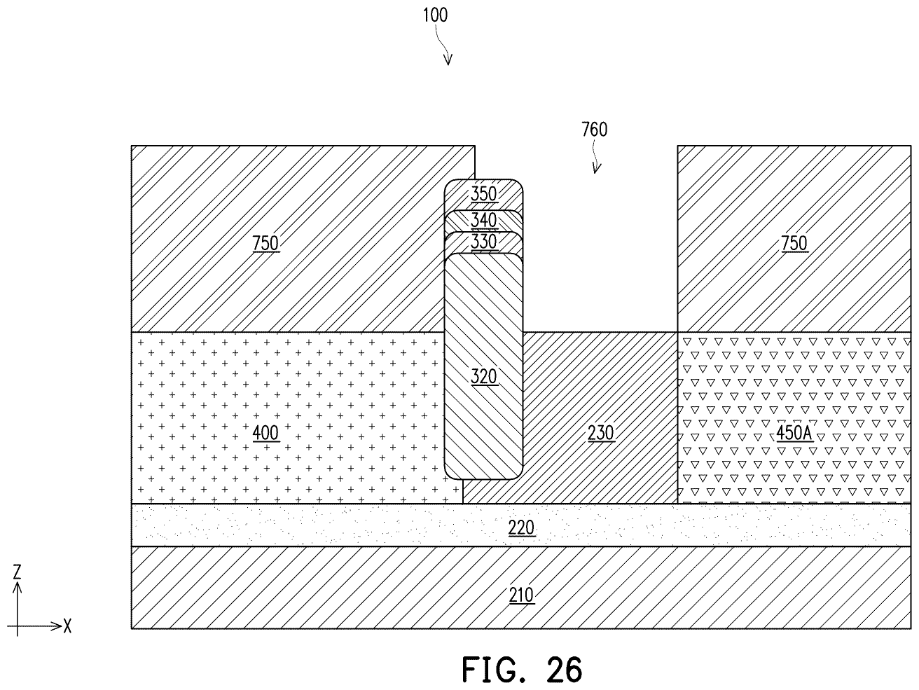

Referring now to FIG. 26, the patterned mask layer 730 is removed. Thereafter, a patterned photoresist mask 750 is formed over the APD 100. The patterned photoresist mask 750 exposes the semiconductor layer 230, as well as a portion of the layer 350, but covers up the rest of the APD 100. In other words, the patterned photoresist mask 750 defines an opening 760 that exposes the upper surface of the semiconductor layer 230 and a portion of the upper surface of the layer 350, as well as side surfaces of the layers 330-350 and a portion of the side surface of the optical absorption layer 320.

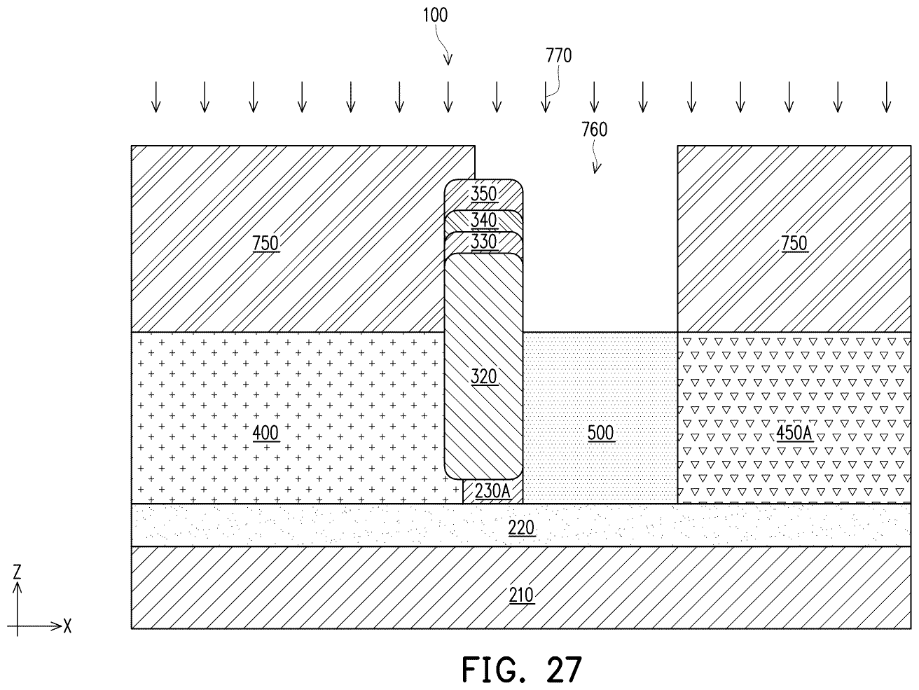

Referring now to FIG. 27, a doping process 770 is performed through the opening 760. In more detail, the doping process 770 implants a P-type dopant material into the portion of the semiconductor layer 230 exposed by the opening 760. The patterned photoresist mask 750 and the layers 330-350 protect the various layers therebelow from being implanted by the dopant material. As a result, the portion of the semiconductor layer 230 exposed by the opening 760 is transformed into the charging layer 500, while the portion of the semiconductor layer 230 covered by the optical absorption layer 320 still remains substantially undoped at this stage of fabrication. The optical absorption layer 320 itself also remains substantially undoped due to the protection offered by the layers 330-350. Again, the P-type dopant material of the doping process 770 is substantially lower than the dose of the P-type dopant material of the doping process 690 (see FIG. 21) used to form the P+ contact 400. As such, the resulting charging layer 500 formed by the doping process 770 is substantially less doped (e.g., having a substantially lower dopant concentration level) compared to the P+ contact 400.

Similar to the other embodiments discussed above, one of the inherent results of the third embodiment of the present disclosure is that the charging layer 500 is still formed directly adjacent to the optical absorption layer 320. For example, the optical absorption layer 320 is formed before the charging layer 500, and the charging layer 500 is formed by doping a portion of the semiconductor layer 230 that is immediately adjacent to the optical absorption layer 320, in a self-aligned manner. Therefore, the optical absorption layer 320 and the charging layer 500 can achieve a substantially vertical interface extending in the Z-direction. Note that another inherent result of the fabrication processes of the third embodiment is that a substantially undoped portion 230A of the semiconductor layer 230 is still disposed below the optical absorption layer 320 after the formation of the charging layer 500. This is because this portion of the semiconductor layer 230A is protected from being doped by the optical absorption layer 320 and the layers 330-350 thereabove during the doping process 770.

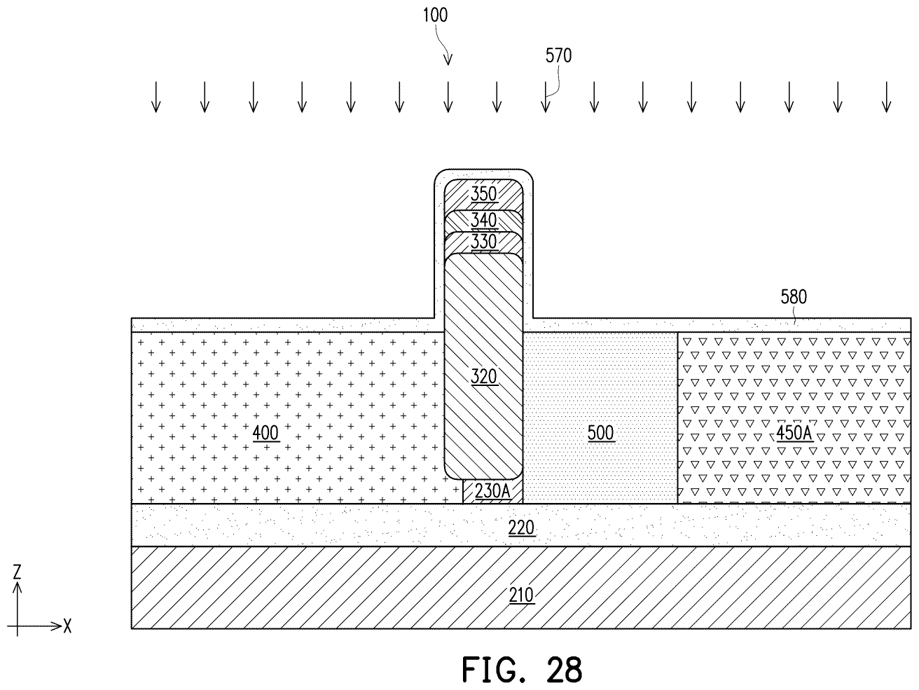

Referring now to FIG. 28, the patterned photoresist mask 750 is removed, for example, through a photoresist ashing or photoresist stripping process. Thereafter, the sputtering process 570 (discussed above with reference to FIG. 14) is performed to the APD 100 to form the spacer layer 580. In some embodiments, the sputtering process 570 forms silicon oxide as the material for the spacer layer 580. The sputtering process 570 is performed such that the spacer layer 580 covers the exposed upper surfaces and side surfaces of the APD 100, including the upper surfaces and the side surfaces of the exposed portions of the optical absorption layer 320 and the layers 330-350. In some embodiments, the sputtering process 570 is configured such that the spacer layer 580 has a substantially uniform thickness. As discussed above, this thickness of the spacer layer 580 may be used to control a width of the spacers that will be formed on the side surfaces of the optical absorption layer 320 and the layers 330-350 subsequently.

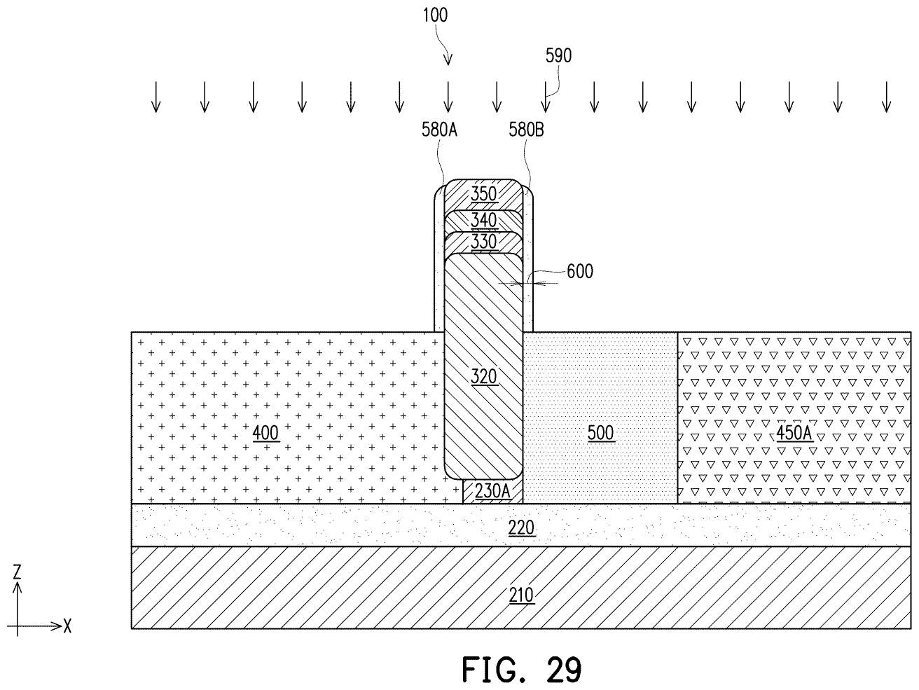

Referring now to FIG. 29, the etching processes 590 (discussed above with reference to FIG. 15) are performed to transform the spacer layer 580 into spacers 580A and 580B. For example, the one or more etching processes 590 may include one or more isotropic etching processes to etch away portions of the spacer layer 580 disposed on the upper surfaces of the P+ contact 400, the layer 350, the charging layer 500, and the N++ contact 450A. The spacers 580A and 580B on the side surfaces of the optical absorption layer 320 and the layers 330-350 mostly remain, since the etching processes 590 merely affect the upper segments of these spacers 580A and 580B. Also as discussed above, the initial thickness of the spacer layer 580 (when it was formed by the sputtering process 570) corresponds to the width 600 of each of the spacers 580A and 580B. However, it is understood that the exact value of the width 600 of each of the spacers 580A and 580B in this third embodiment need not necessarily be the same as the value of the width 600 of each of the spacers 580A and 580B in the second embodiment (see FIG. 15).

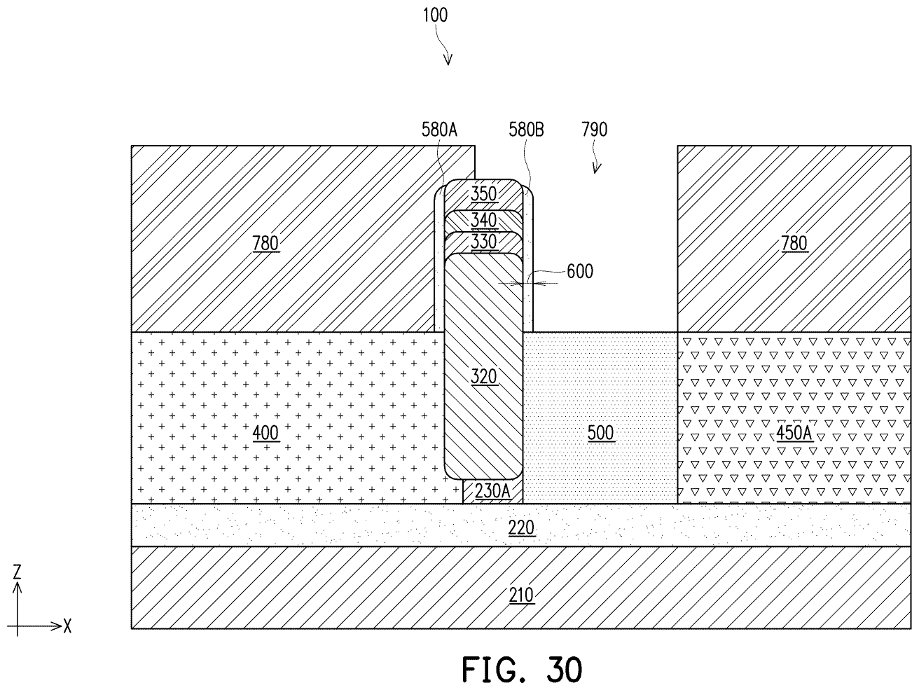

Referring now to FIG. 30, a patterned photoresist mask 780 is formed over a portion of the APD 100. For example, the patterned photoresist mask 780 is formed to cover the P+ contact 400, over a portion of the optical absorption layer 320 and the layers 330-350 above, and over the N++ contact 450A. Thus, the patterned photoresist mask 780 defines an opening 790 that exposes the charging layer 500, as well as a portion of the layer 350 and the spacer 580B.

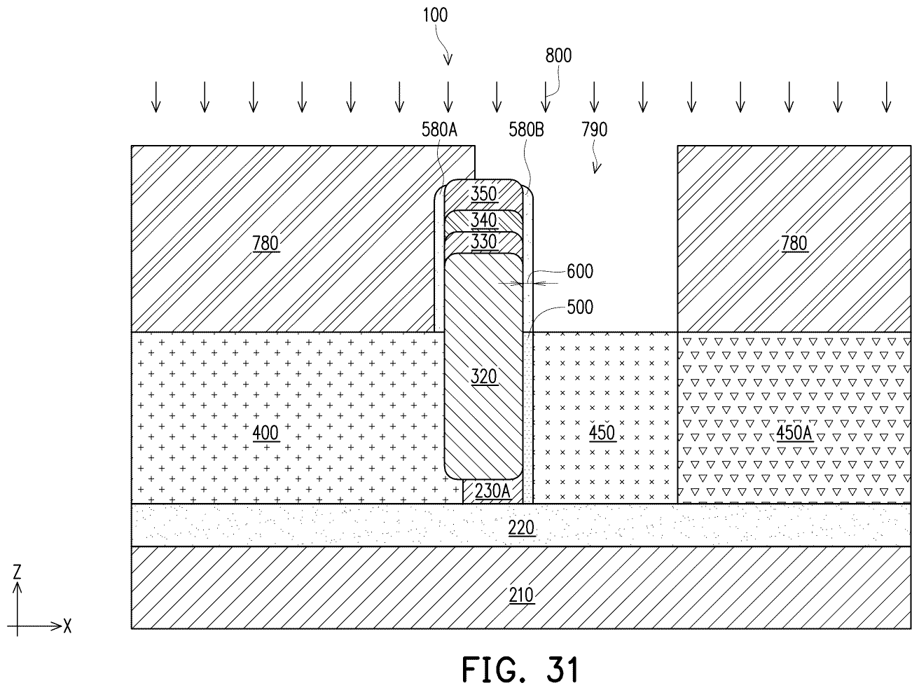

Referring now to FIG. 31, a doping process 800 is performed to transform the portion of the charging layer 500 not covered by the patterned photoresist mask 780 or by the spacer 580B into the N+ contact 450. For example, the doping process 800 may implant an N-type dopant material into the exposed portion of the charging layer 500. The patterned photoresist mask 780, as well as the layers 330-350 and the spacer 580B, protect the various layers therebelow from being implanted by the dopant material. As a result, the exposed portion of the charging layer 500 is transformed into the N+ contact 450, while the portion of the charging layer 500 to the “right side” of the optical absorption layer 320 and covered by the spacer 580B still remains substantially undoped at this stage of fabrication. Note that the doping process 800 may be configured to use a lighter implant dosage compared to the doping process 710 (see FIG. 23) used to form the N++ contact 450A. As such, the N+ contact 450 formed as a result of the doping process 800 has a lower dopant concentration level than the N++ contact 450A, even though both the N+ contact 450 and the N++ contact 450A are doped with an N-type dopant. It is understood that the N+ contact 450 and the N++ contact 450A collectively correspond to the N+ contact discussed above with reference to FIG. 1.

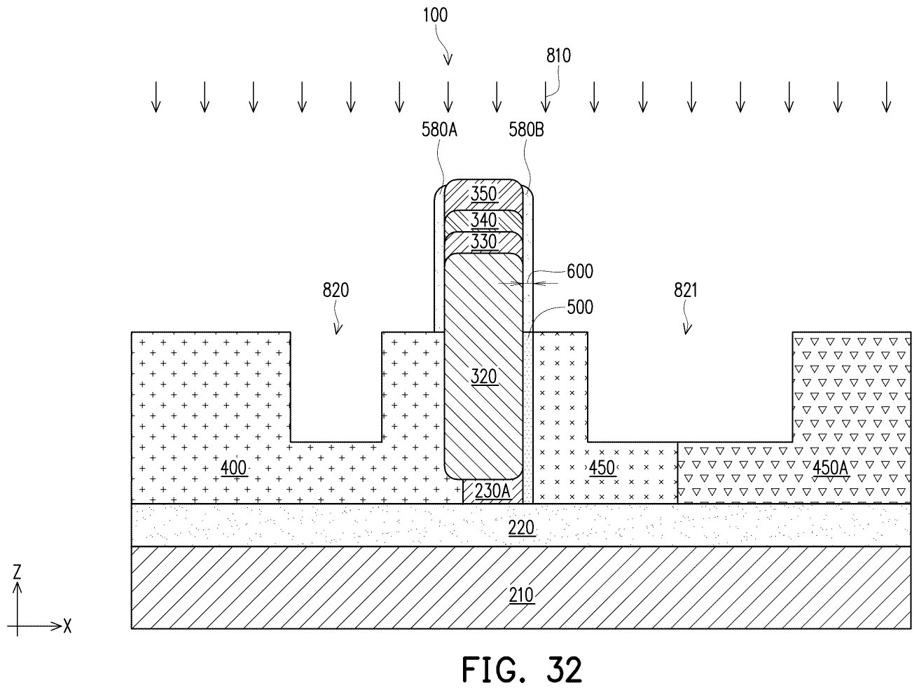

Referring now to FIG. 32, the patterned photoresist mask 780 is removed, for example, by a photoresist ashing process or a photoresist stripping process. Thereafter, one or more etching processes 810 are performed to form a plurality of openings. For example, the one or more etching processes 810 may etch an opening 820 into the P+ contact 400, as well as an opening 821 into the N+ contact 450 and the N++ contact 450A.

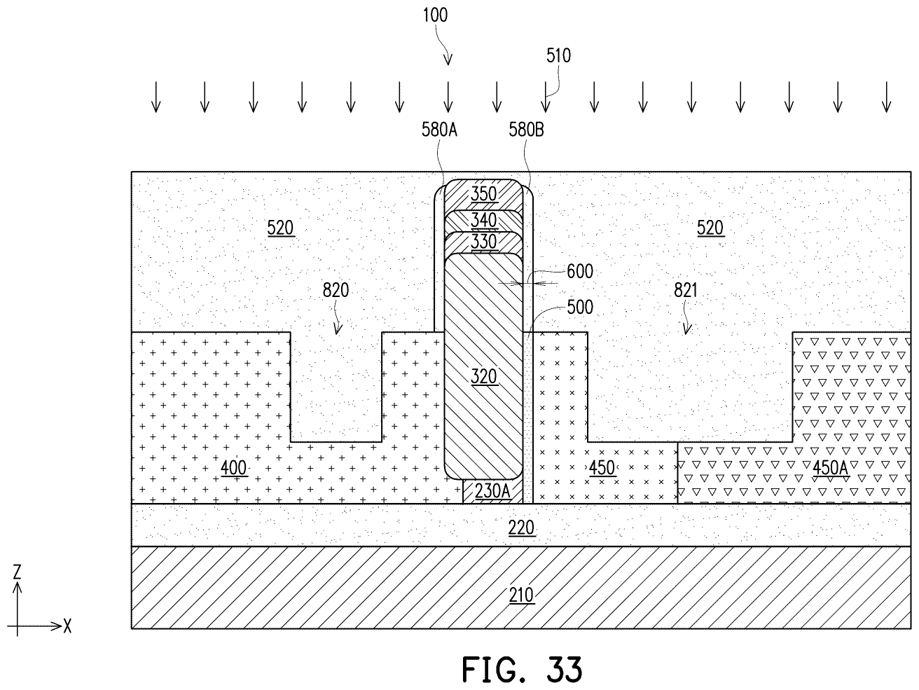

Referring now to FIG. 33, the deposition process 510 discussed above with reference to FIG. 11 is performed to form the passivation layer 520 over the other components of the APD 100. For example, the deposition process 510 may include a CVD process, a PVD process, an ALD process, or combinations thereof, in order to deposit a dielectric material as the passivation layer. In some embodiments, the deposited dielectric material may include a silicon nitride material or a silicon oxide material. The passivation layer 520 completely fills the openings 820-821. The resulting passivation layer 520 protects the components of the APD 100 therebelow from contaminant particles and/or moisture.

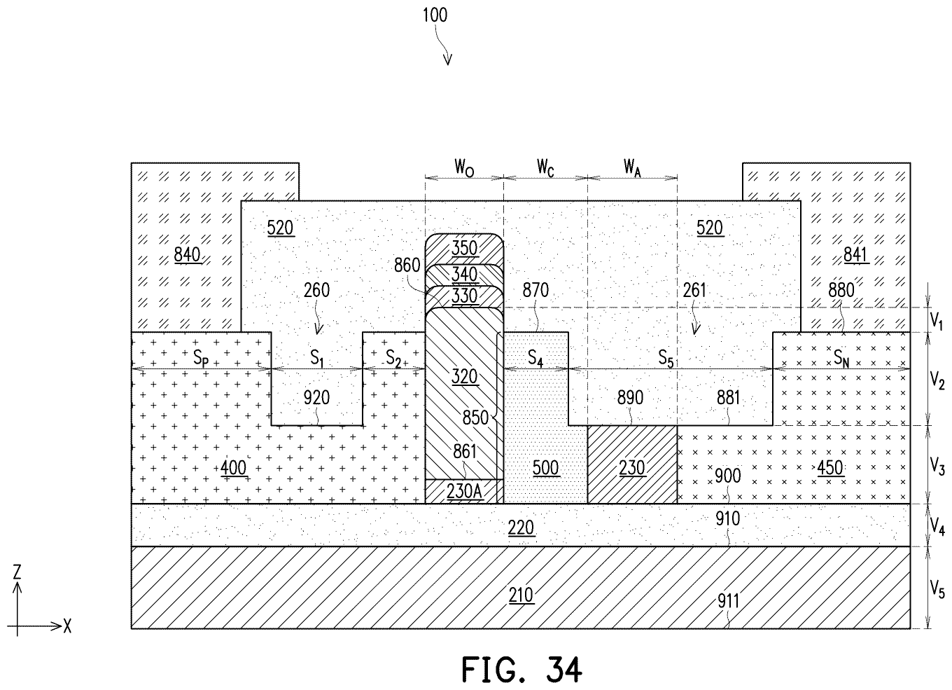

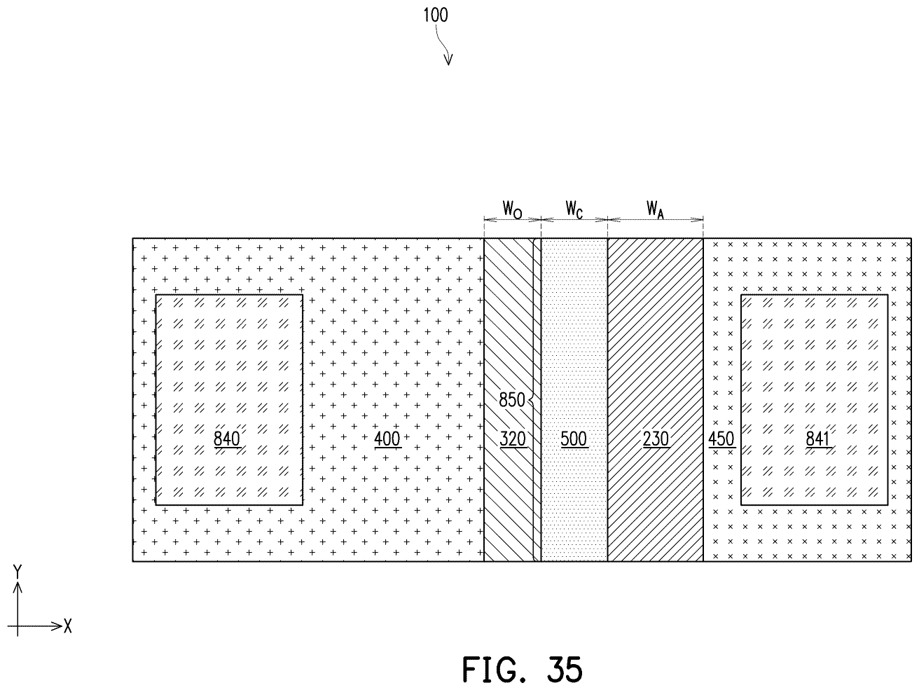

The various dimensions and physical characteristics of the APD 100 will now be discussed in more detail with reference to FIGS. 34 and 35, which are a fragmentary cross-sectional side view and a planar top view, respectively, of the APD 100 according to an embodiment of the present disclosure. For example, the APD 100 shown in FIGS. 34 and 35 largely corresponds to the APD fabricated according to the first embodiment of the fabrication process flow discussed above with reference to FIGS. 1-11. In this particular embodiment, the N+ contact 450, but not the N++ contact, is formed. Furthermore, the particular embodiment shown in FIG. 34 does not utilize the spacers 580A and 580B, which are implemented in the embodiment of the APD 100 fabricated according to the second embodiment (see FIG. 18) and the third embodiment (see FIG. 33). Nevertheless, it is understood that the discussions below regarding the dimensions and other physical characteristics of the APD 100 apply equally to the APD 100 fabricated according to the second and third embodiments of the fabrication process flow, unless otherwise noted. It is also understood that FIGS. 34-35 illustrate a conductive pad 840 and a conductive pad 841 over the P+ contact 400 and the N+ contact 450, respectively. These conductive pads 840 and 841 are implemented to provide electrical connectivity to the APD 100.

As shown in FIGS. 34-35, the charging layer 500 is located directly adjacent to (e.g., directly abutting) the optical absorption layer 320 and the segment 230A of the semiconductor layer 230. In other words, a side surface of the charging layer 500 forms an interface 850 with the side surfaces of the optical absorption layer 320 and the segment 230A, where this interface 850 extends substantially vertically in the Z-direction. This is one of the unique physical characteristics of the APD 100 fabricated according to the present disclosure. Unlike the APD 100 herein, APDs not fabricated using the unique fabrication process flow of the present disclosure typically rely on photolithography to define the locations of their optical absorption layer and charging layer. Unfortunately, since photolithography has limitations with respect to precision—particularly as semiconductor device sizes continue to shrink—one result is that the optical absorption layer and the charging layer may not be directly abutting one another. For example, there may be a buffer region (e.g., an undoped region) between the optical absorption layer and the charging layer. Such a buffer region is not configured to detect light, and therefore it constitutes wasted space in the APD, which is undesirable.

Another possible result of relying on photolithography to define the locations of the optical absorption layer and the charging layer is that the charging layer may not have an entirely vertical side surface that is facing the optical absorption layer. Rather, the charging layer may have a segmented side surface, where a portion of the side surface protrudes further into the segment of semiconductor layer below the optical absorption layer. Unfortunately, this could cause the strongest electric field to be in the segment of the semiconductor layer below the optical absorption layer, which means that the electric field in the optical absorption layer itself may not be sufficiently strong. Consequently, the performance of the APD may be degraded.

In comparison, the APD 100 herein utilizes self-aligned processes to define the locations of the optical absorption layer 320 and the charging layer 500. This allows the charging layer 500 to be formed directly adjacent to the optical absorption layer 320 and the segment 230A, while achieving a substantially linear interface 850, which extends vertically upwards. One benefit is that the buffer region is eliminated, which preserves precious device real estate and improves optical detection efficiency. Another benefit is that the strongest electric field is maintained within the optical absorption layer 320, which helps to improve the performance of the APD 100.

It is noted that although FIGS. 34-35 illustrate a distinct interface 850, this is done for reasons of simplicity. In an actually fabricated device, the interface 850 may have a more gradient-like profile. This is because dopant diffusion may occur between the charging layer 500 (e.g., containing silicon doped with the P-type dopant) and the optical absorption layer 320 (e.g., containing substantially undoped germanium), and also between the charging layer 500 and the segment 230A (e.g., containing substantially undoped silicon). Due to the dopant diffusion, the interface 850 in an actually fabricated APD 100 may not appear as a one-dimensional line but may span a certain distance in the X-direction horizontally. In other words, the interface 850 may have a width measured in the X-direction, where within this width, the dopant concentration level is greater towards the charging layer 500 and lower toward the optical absorption layer 320 (e.g., thereby exhibiting the gradient-like profile). In some embodiments, such a width may be about 8%-12% of a maximum width W_{C} of the charging layer 500, where the maximum width W_{C} itself may be in a range between about 50 nanometers (nm) and about 100 nm. Regardless of the exact amount of horizontal span of the interface 850, or its gradient-like profile, it is still understood that the interface 850 extends substantially vertically and linearly in the Z-direction, which is one of the unique physical traits of the APD 100 of the present disclosure.

FIGS. 34-35 also illustrate a horizontal dimension W_{O} for the optical absorption layer 320 and a horizontal dimension W_{A} for the undoped semiconductor layer 230 disposed between the charging layer 500 and the N+ contact 450, where both W_{O} and W_{A} are measured in the X-direction. In some embodiments, W_{O} is greater than or equal to W_{A}, and W_{A} is substantially greater than W_{C}. In some embodiments, the horizontal dimension W_{O} is in a range between about 300 nm and about 1000 nm, and the horizontal dimension W_{A} is in a range between about 200 nm and about 400 nm.

FIG. 34 also illustrates a plurality of horizontal dimensions S₁, S₂, S₄, S₅, S_{P}, and S_{N}. In more detail, the horizontal dimension S_{P} corresponds to a width of a portion of the P+ contact 400 disposed to the “left” of the opening 260 (and away from the optical absorption layer 320). The horizontal dimension S₁ corresponds to a width of the opening 260. The horizontal dimension S₂ corresponds to a width of a portion of the P+ contact 400 disposed to the “right” of the opening 260 (e.g., the portion directly abutting the optical absorption layer 320). The horizontal dimension S₄ corresponds to a width of a narrower upper portion of the charging layer 500 directly abutting the optical absorption layer 320. The horizontal dimension S₅ corresponds to a width of the opening 261. The horizontal dimension S_{N} corresponds to a width of a portion of the N+ contact 450 disposed to the “right” of the opening 261 (and away from the optical absorption layer 320). In some embodiments, S₁ need not be substantially different from S₅, but S₁ and S₅ are greater than or equal to W_{O}. In some embodiments, S₃ is much greater than S₂ and S₄, but S₂ and S₄ need not be substantially different from one another. In some embodiments, S₁ is in a range between about 550 nm and about 650 nm, and S₂ is in a range between about 40 nm and about 60 nm. It is understood that these dimension ranges above are not randomly chosen but specifically configured to optimize device performance. For example, these ranges are configured to properly tune the strength of electric fields and/or the optical absorption efficiency of the various components of the APD 100.

One of the benefits of the present disclosure is that the horizontal dimensions W_{A} and W_{C} can be precisely controlled. This is because the horizontal dimensions W_{A} and W_{C} are defined through the self-aligned processes discussed above, rather than by relying on the capabilities of photolithography alone. As such, process uniformity can be improved. For example, a plurality of APDs 100 formed using the process flows of the present disclosure may have substantially similar values for the horizontal dimensions W_{A} and W_{C}, which is desirable for a quality control standpoint. In comparison, APDs formed by other process flows may have significantly greater variations among the different APDs in terms of the dimensions of their optical absorption layer and charging layer regions.

FIG. 34 also illustrates a plurality of vertical dimensions V₁, V₂, V₃, V₄, and V₅ (each of which is measured in the Z-direction). For example, V₁ is a vertical dimension that corresponds to a protrusion of the optical absorption layer 320 above the charging layer 500 vertically. For example, an uppermost surface 860 of the optical absorption layer 320 is at a more elevated position vertically than an uppermost surface 870 of the charging layer 500. The difference between these uppermost surfaces 860 and 870 in terms of distance is reflected by the vertical dimension V₁. Note that the N+ contact 450 has uppermost surface 880 that has a substantially similar vertical elevation as the uppermost surface 870 of the charging layer 500. Therefore, it may be said that the vertical dimension V₁ corresponds to a vertical distance between the uppermost surface 860 of the optical absorption layer 320 and the uppermost surface 880 of the N+ contact 450 as well.

V₂ is a vertical dimension that corresponds to a protrusion of the N+ contact 450 above the semiconductor layer 230 vertically. For example, the uppermost surface 880 of the N+ contact 450 is at a more elevated position vertically than an uppermost surface 890 of the semiconductor layer 230. The difference between these uppermost surfaces 880 and 890 in terms of distance is reflected by the vertical dimension V₂. Note that the N+ contact 450 has another upwardly-facing surface 881 that is exposed by the opening 261, and this upwardly-facing surface 881 is at the same vertical elevation as the uppermost surface 890 of the semiconductor layer 230. Therefore, it may be said that the vertical dimension V₂ corresponds to a vertical distance between the uppermost surface 880 and the upwardly-facing surface 881 of the N+ contact 450 as well. It is also understood that the discussions above regarding V₂ may apply not just to the N+ contact 450, but also to the P+ contact 400 as well.

V₃ is a vertical dimension that corresponds to distance between the upwardly-facing surface 881 and an uppermost surface 900 of the insulator layer 220, which also coincides with the bottommost surface of the N+ contact 450. V₄ is a vertical dimension that corresponds to distance between the uppermost surface 900 and an uppermost surface 910 of the substrate 210, which also coincides with the bottommost surface of the insulator layer 220. In other words, V₄ corresponds to a thickness of the insulator layer 220. V₅ is a vertical dimension that corresponds to distance between the uppermost surface 910 and a bottommost surface 911 of the substrate 210. In other words, V₅ corresponds to a thickness of the substrate 210. It is also understood that the discussions above regarding V₃ may apply not just to the N+ contact 450, but also to the P+ contact 400 as well.

It is understood that the vertical dimension V₁ is dependent on the process configurations of the selective growth process 310 (see FIG. 6) discussed above. For example, a longer growth time may result in a taller V₁. In the illustrated embodiment, V₁ is a positive value, meaning that the uppermost surface 860 is more vertically elevated than the uppermost surface 870. However, this need not be the case in alternative embodiments. In other words, the uppermost surface 860 may be less vertically elevated than the uppermost surface 870 in some embodiments. Meanwhile, the vertical dimensions V₂ and V₃ are configured based on an optical wavelength of the light that is to be detected by the APD 100, and the vertical dimensions V₄ and V₅ may be flexibly configured based on fabrication processing needs.

Another unique physical characteristic of the APD 100 herein pertains to the relative vertical dispositions between the bottommost surface 861 of the optical absorption layer 320 and the upwardly-facing surface 890 (of the semiconductor layer 230) or the upwardly-facing surface 881 (of the N+ contact 450) or an upwardly-facing surface 920 (of the P+ contact 400). In more detail, an APD formed by a fabrication process other than the present disclosure may simultaneously etch openings for its optical absorption layer and the N+ and P+ contacts. That is, the opening within which the optical absorption layer is formed is etched the same time as the openings within the N+ contact and the P+ contact, and the openings are etched within the same type of material (e.g., silicon). Accordingly, the optical absorption layer formed by fabrication processes other than the present disclosure will typically have a bottommost surface that is substantially co-planar with, or at a similar vertical elevation, as the upwardly-facing surfaces of the P+ and N+ contacts exposed by the openings in the P+ and N+ contacts.

In contrast, the unique fabrication process flows of the present disclosure either etch the opening 300 (see FIG. 5) for the optical absorption layer 320 after the openings 260-261 (see FIG. 3) are etched for the P+ contact 400 and the N+ contact 450, as is the case for the first and second embodiments of the process flow herein, or it etches the opening 740 (see FIG. 24) for the optical absorption layer 320 before the openings 820-821 (see FIG. 32) are etched for the P+ contact and the N+ contact 450 and the N++ contact 450A, as is the case for the third embodiment of the process flow herein. Since the openings for the optical absorption layer 320 and the P+ contact 400 and the N+ contact 450 are etched are different times, the depths of these openings may be different. In fact, it may be desirable to configure the opening 300 or the opening 740 for the optical absorption layer 320 to have a deeper depth than the openings for the P+ contact 400 and the N+ contact 450, so as to maximize the optical detection efficiency of the APD 100. Therefore, one of the inherent results of the unique fabrication process flow herein is that the bottommost surface 861 of the optical absorption layer 320 is located at a lower vertical elevation than the upwardly-facing surfaces 920 of the P+ contact 400 located underneath the opening 260, and/or than the upwardly-facing surface 890 of the semiconductor layer 230 or the upwardly-facing surface 881 of the P+ contact 400 located underneath the opening 260. Such a unique physical characteristic, alone or in combination with the other unique physical characteristics discussed above, may be used as evidence to determine whether an APD was fabricated using the unique process flows of the present disclosure.

It is also understood that while the segment 230A of the semiconductor layer 230 located underneath the optical absorption layer 320 contains mostly undoped silicon, some portions thereof may contain a dopant material as well. For example, at or near an interface between the P+ contact 400 and the segment 230A of the semiconductor layer 230, dopant diffusion may occur, such that the P-type dopant may diffuse from the P+ contact 400 into portions of the segment 230A located near the interface. As a result, the portion of the segment 230A located adjacent to the P+ contact 400 may become slightly doped with the P-type dopant as well, even though a rest of the segment 230A remains substantially undoped.

It is further understood that the APD 100 (or at least portions thereof) may function similarly to a waveguide. Suppose that W=S₂+W_{O}+S₄, h=V₃, and that H=V₂+V₃. Also suppose that Pₒₜₑₗ=a total amount of optical power, and that Pₒₚₜ is in a range between about 0 dBm and about 10 dBm. In a single-mode condition of the waveguide, the following conditions need to be satisfied:

$$\frac{W}{H} \leq 0.3 + \frac{r}{\sqrt{1 - {r}^{2}}} , r = \frac{h}{H} \geq 0.5$$

In addition, for S₁ and S₅:

$$0.01 \times {P}_{total} \leq {\int }_{0}^{d} {P}_{opt} \cdot dx ,$$

meaning that the total energy of optical power expansion to both sides of the platform needs to be less than 0.01%, an optional condition.

In a multi-mode condition of the waveguide, for S₁ and S₅:

$$0.05 \times {P}_{total} \leq {\int }_{0}^{d} {P}_{opt} \cdot dx ,$$

which is an optional condition.

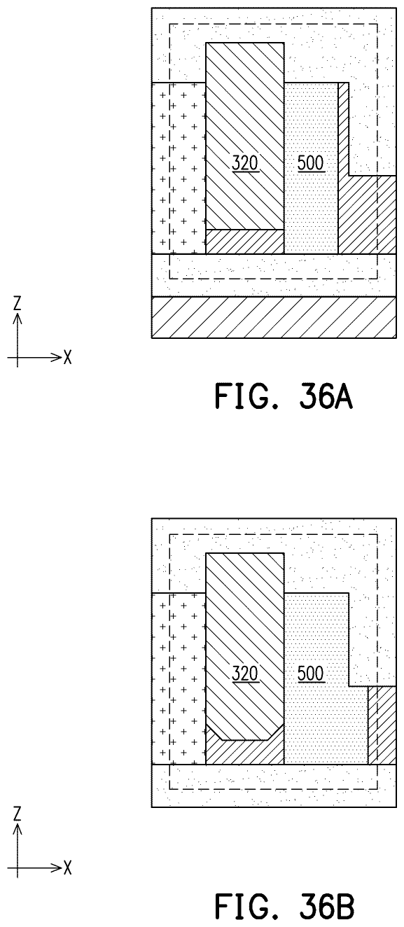

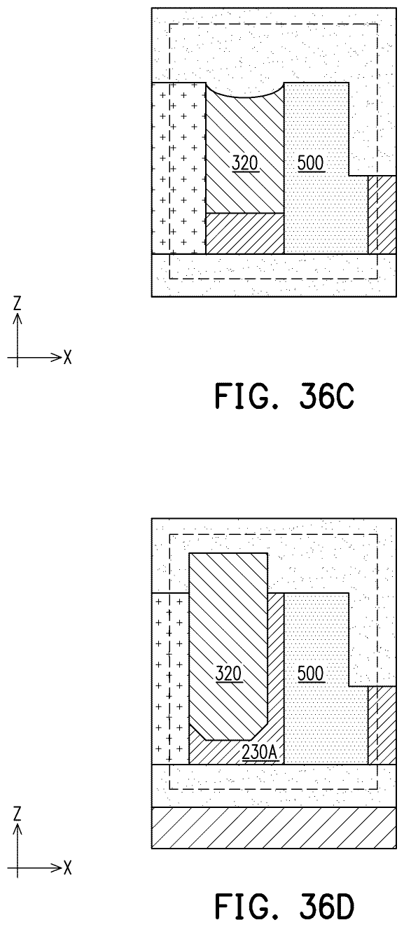

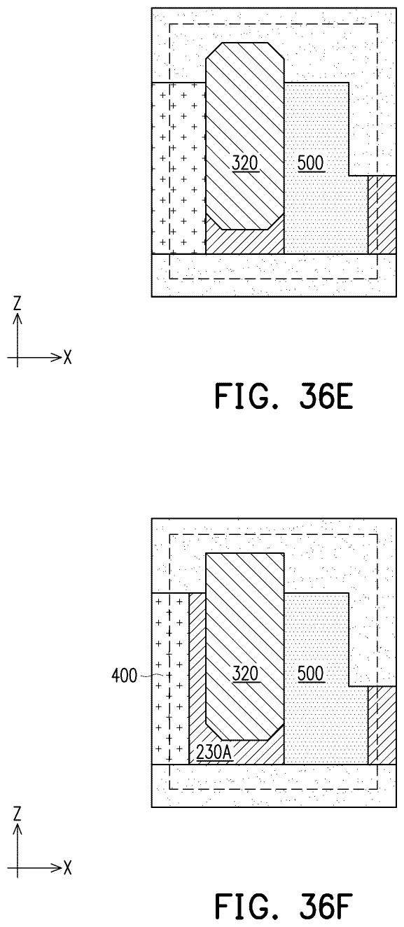

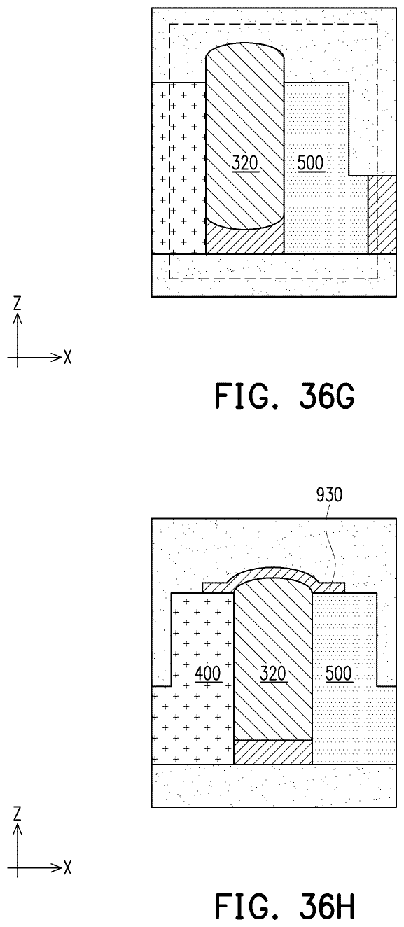

It is further understood that the exact physical appearance of the optical absorption layer 320 and/or its relative disposition with respect to the charging layer 500 may be configured differently in different embodiments. For example, FIGS. 36A-36H each illustrates a diagrammatic fragmentary cross-sectional side view of a portion of the APD 100 that contains the optical absorption layer 320 according to a different embodiment of the present disclosure.

In more detail, FIG. 36A illustrates an optical absorption layer 320 having a substantially rectangular shape, where both an uppermost surface and a bottommost surface of the optical absorption layer 320 are substantially flat. FIG. 36B illustrates an optical absorption layer 320 having a polygonal shape, where an uppermost surface of the optical absorption layer 320 is substantially flat, but a bottom portion of the optical absorption layer 320 has a trapezoidal shape. FIG. 36C illustrates an optical absorption layer 320 having an arbitrary shape, where an uppermost surface of the optical absorption layer 320 is substantially rounded or curved downwards (e.g., having a concave shape), but a bottommost surface of the optical absorption layer 320 is substantially flat. FIG. 36D illustrates an optical absorption layer 320 having a polygonal shape that is similar to the shape of FIG. 36B, but the optical absorption layer 320 is spaced apart from the charging layer 500. For example, a portion of a semiconductor layer 230A is disposed between the optical absorption layer 320 and the charging layer 500. FIG. 36E illustrates an optical absorption layer 320 having a polygonal shape, where an upper portion of the optical absorption layer 320 and a bottom portion of the optical absorption layer 320 each have a trapezoidal shape. FIG. 36F illustrates an optical absorption layer 320 having a polygonal shape that is similar to the shape of FIG. 36B, but the optical absorption layer 320 is spaced apart from the P+ contact 400. For example, a portion of a semiconductor layer 230A is disposed between the optical absorption layer 320 and the P+ contact 400. FIG. 36G illustrates an optical absorption layer 320 having an arbitrary shape, where an uppermost surface of the optical absorption layer 320 is substantially rounded or curved upwards (e.g., having a convex shape), and a bottommost surface of the optical absorption layer 320 is substantially rounded or curved downwards (e.g., having a convex shape). FIG. 36H illustrates an optical absorption layer 320 having an arbitrary shape, where an uppermost surface of the optical absorption layer 320 is substantially rounded or curved upwards (e.g., having a convex shape), and a bottommost surface of the optical absorption layer 320 is substantially flat. In addition, a passivation layer is implemented on not just an uppermost surface of the optical absorption layer 320, but also on portions of an uppermost surface of the P+ contact 400 and an uppermost surface of the charging layer 500. The passivation layer 930 protects the charging layer 500 from being exposed to air or other sources of contamination.

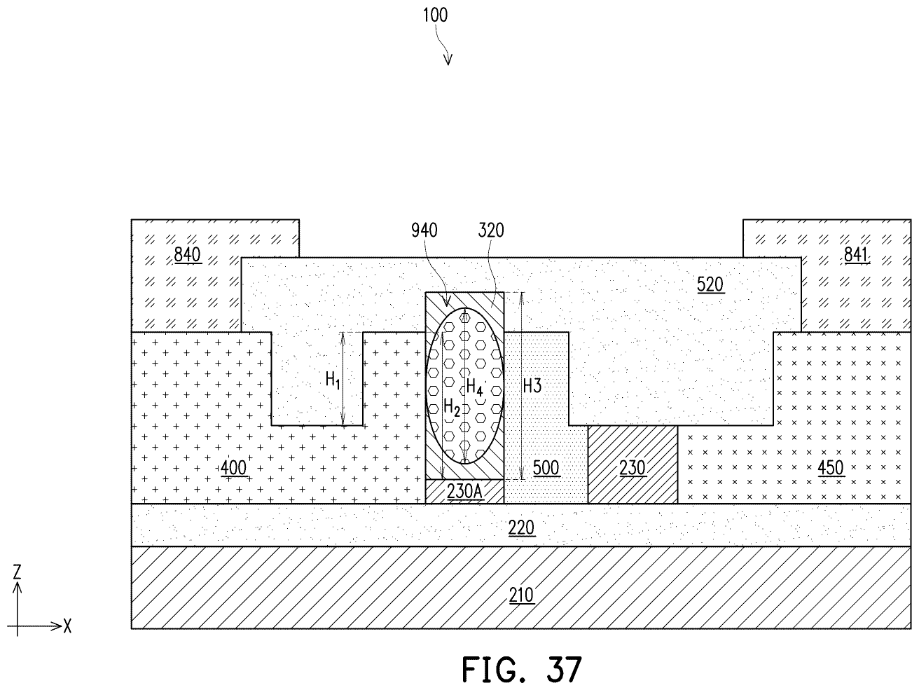

Referring now to FIG. 37, an optical intensity profile 940 is illustrated in a cross-sectional side view of the APD 100. The optical intensity profile 940 is associated with the optical radiation (e.g., in the form of a light beam) that is injected into the APD 100, for example, into the optical absorption layer 320. In order to ensure that the optical radiation is fully absorbed by the optical absorption layer 320, the various dimensions of the APD 100 are specifically configured. For example, a dimension H₁ corresponds to an amount of vertical protrusion of the P+ contact 400. In some embodiments, H₁ is substantially equal to the vertical dimension V₂ discussed above with reference to FIG. 34. A dimension H₂ corresponds to an amount of overlap between the optical absorption layer 320 and the P+ contact 400. In some embodiments, H₂ is greater than about 10 nm. A dimension H₃ corresponds to an overall height of the optical absorption layer 320. A dimension H₄ corresponds to the desired length (in the Z-direction) of the optical intensity profile 940. In some embodiments, H₃ is greater than or equal to H₄, since H₃ it is desirable for H₃ to overlay the optical intensity profile 940.

The discussions above pertain to implementing the APD 100 as a part of an image sensor device. However, it is understood that the APD 100 (or the components thereof) can also be used in the production of three-dimensional integrated circuits (3DICs). For example, a 3DIC fabrication system may include an optical communication path in which a photodetector is used. Such a photodetector is configured to detect light, and it may function in a similar manner as the APD 100 discussed above. Therefore, in some embodiments, the APD 100 may be implemented as a replacement of the photodetector in the optical communication path of the 3DIC fabrication system. In such a system, the APD 100 may work in conjunction with waveguide components to establish an optical communication path. The structural arrangement of the APD 100 in such a system (e.g., as a photodetector in the 3DIC system) is otherwise substantially identical to the APD 100 discussed above.

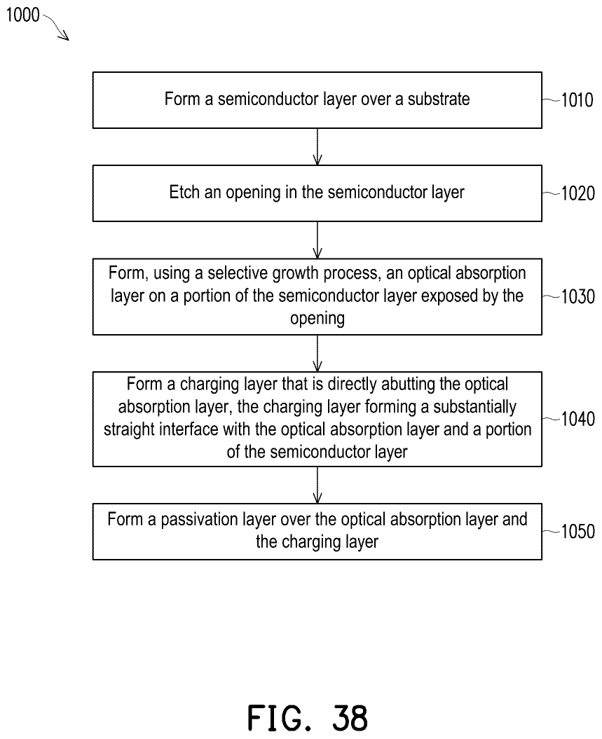

FIG. 38 is a flowchart illustrating a method 1000 of fabricating an image sensor device, for example, an APD, according to embodiments of the present disclosure. The method 1000 includes a step 1010 to form a semiconductor layer over a substrate.

The method 1000 includes a step 1020 to etch an opening in the semiconductor layer.

The method 1000 includes a step 1030 to form, using a selective growth process, an optical absorption layer on a portion of the semiconductor layer exposed by the opening.

The method 1000 includes a step 1040 to form a charging layer that is directly abutting the optical absorption layer. The charging layer forms a substantially straight interface with the optical absorption layer and a portion of the semiconductor layer

The method 1000 includes a step 1050 to form a passivation layer over the optical absorption layer and the charging layer.

It is understood that the method 1000 may include further steps performed before, during, or after the steps 1010-1050. For example, in some embodiments, the method 1000 may include a step of forming, through a first doping process, a P-type contact in a first portion of the semiconductor layer disposed to a first side of the optical absorption layer. The optical absorption layer and a second portion of the semiconductor layer are protected from being doped by the first doping process. The method 1000 may further include a step of forming, through a second doping process, an N-type contact in a second portion of the semiconductor layer disposed to a second side of the optical absorption layer. The second side is opposite the first side. The optical absorption layer and the P-type contact are protected from being doped by the second doping process. The charging layer is formed in a third portion of the semiconductor layer through a third doping process that is performed after the second doping process. In some embodiments, the method 1000 may further include a step of forming a mask structure over the optical absorption layer before the P-type contact or the N-type contact is formed. The mask structure protects the optical absorption layer from being doped by the first doping process and the second doping process.

As another example, in some embodiments, the method 1000 may include a step of forming, through a first doping process, a P-type contact in a first portion of the semiconductor layer disposed to a first side of the optical absorption layer. The optical absorption layer and a second portion of the semiconductor layer are protected from being doped by the first doping process. The charging layer is formed in a first segment of the second portion of the semiconductor layer through a second doping process that is performed after the first doping process. The method 1000 may further include a step of forming, through a third doping process, an N-type contact in a second segment of the second portion of the semiconductor layer disposed to a second side of the optical absorption layer. The second side is opposite the first side. The optical absorption layer and the P-type contact are protected from being doped by the second doping process. In some embodiments, the method 1000 may further include the following steps: forming a mask structure over the optical absorption layer before the P-type contact is formed; forming a spacer layer after the charging layer is formed, wherein the spacer layer is formed over the P-type contact, over the mask structure, over the charging layer, and over the second portion of the semiconductor layer; transforming the spacer layer into a first spacer and a second spacer disposed on opposite sides surfaces of the mask structure; and forming, through a fourth doping process, a further N-type contact in a first portion of the charging layer, wherein a second portion of the charging layer directly abutting the optical absorption layer is protected from the fourth doping process by at least the second spacer.

As another example, in some embodiments, the method 1000 may include steps performed before the optical absorption layer is formed. These steps may include a step of forming, through a first doping process, a P-type contact in a first portion of the semiconductor layer. A second portion and a third portion of the semiconductor layer are protected from being doped by the first doping process. The method 1000 may further include a step of forming, through a second doping process, an N-type contact in the second portion of the semiconductor layer. The third portion of the semiconductor layer and the P-type contact are protected from being doped by the second doping process. The optical absorption layer and the charging layer are formed in the third portion of the semiconductor layer. In some embodiments, the method 1000 may further include the following steps: forming a mask structure over the optical absorption layer before the charging layer is formed, wherein the charging layer is formed by a third doping process that implants a P-type dopant into the third portion of the semiconductor layer directly abutting the optical absorption layer, and wherein the mask structure protects the optical absorption layer from being implanted during the third doping process; forming a spacer layer after the third doping process, wherein the spacer layer is formed over the P-type contact, over the mask structure, over the charging layer, and over the N-type contact; transforming the spacer layer into a first spacer and a second spacer disposed on opposite sides surfaces of the mask structure; and forming, through a fourth doping process, a further N-type contact in a first portion of the charging layer, wherein a second portion of the charging layer directly abutting the optical absorption layer is protected from the fourth doping process by at least the second spacer. For reasons of simplicity, these additional steps are not discussed herein in detail.

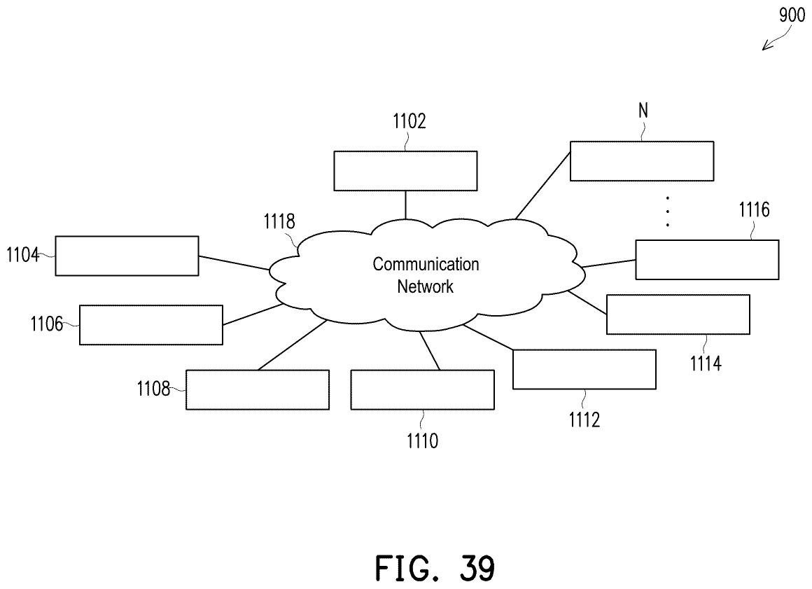

FIG. 39 illustrates an integrated circuit fabrication system 1100 according to embodiments of the present disclosure. The fabrication system 1100 includes a plurality of entities 1102, 1104, 1106, 1108, 1110, 1112, 1114, 1116 . . . , N that are connected by a communications network 1118. The network 1118 may be a single network or may be a variety of different networks, such as an intranet and the Internet, and may include both wire line and wireless communication channels.

In an embodiment, the entity 1102 represents a service system for manufacturing collaboration; the entity 1104 represents an user, such as product engineer monitoring the interested products; the entity 1106 represents an engineer, such as a processing engineer to control process and the relevant recipes, or an equipment engineer to monitor or tune the conditions and setting of the processing tools; the entity 1108 represents a metrology tool for IC testing and measurement; the entity 1110 represents a semiconductor processing tool, such an EUV tool that is used to perform lithography processes; the entity 1112 represents a virtual metrology module associated with the processing tool 1110; the entity 1114 represents an advanced processing control module associated with the processing tool 1110 and additionally other processing tools; and the entity 1116 represents a sampling module associated with the processing tool 1110.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 1114 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 1100 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 1100 may enable collaboration and information access in such areas as design, engineering, and processing, metrology, and advanced processing control. Another capability provided by the IC fabrication system 1100 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or an advanced process control (APC) module, and may enable wafer data from the online or in site measurement with the metrology tool integrated in the associated processing tool.

The advanced lithography process, method, and materials described above can be used in many applications, including applications where the transistors are implemented as fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the transistors may also be implemented using multi-channel devices such as Gate-All-Around (GAA) devices. To the extent that the present disclosure refers to a fin structure or FinFET devices, such discussions may apply equally to the GAA devices.

The present disclosure may offer advantages over conventional devices. However, it is understood that not all advantages are discussed herein, different embodiments may offer different advantages, and that no particular advantage is required for any embodiment. One advantage is improved device performance. In more detail, whereas other photonic devices rely on photolithography to define the locations of optical absorption layer and charging layer regions, the photonic device of the present disclosure utilizes self-aligned processes to define the locations of the optical absorption layer and the charging layer regions. Accordingly, the charging layer can be formed directly adjacent to the optical absorption layer, such that the charging layer forms a substantially vertically linear interface with the optical absorption layer and a segment of undoped silicon therebelow. The direct abutment between the charging layer and the optical absorption layer eliminates a buffer region that is often present between the charging layer and the optical absorption layer in some other types of photonic devices. Since such a buffer region is not configured to detect light, it may constitute wasted space on the photonic device, thereby resulting in lower optical detection efficiency for these other types of photonic devices. In contrast, the photonic device of the present disclosure offers enhanced optical detection efficiency due at least in part to the elimination of the buffer region.

Furthermore, certain other types of photonic devices not fabricated according to the unique process flows of the present disclosure may have a non-linear interface between the charging layer and the optical absorption layer and the undoped silicon segment below the optical absorption layer. For example, the charging layer and the optical absorption layer may form a first interface, and the charging layer and the undoped silicon segment may form a second interface, where the first interface and the second interface are misaligned (e.g., have different horizontal positions). This could lead to an undesirable electric field distribution within the photonic device, which may also adversely impact the performance of the photonic device. In comparison, as an inherent result of the unique self-alignment process flow performed herein, the charging layer may define an interface with the optical absorption layer and the undoped silicon segment below collectively, where the interface extends in a substantially vertical direction. This allows the electric field within the photonic device to achieve a desired distribution, which in turn improves the performance of the photonic. Another benefit is that the locations and/or sizes of the optical absorption layer and/or the charging layer can be flexibly adjusted (e.g., by configuring the thickness of the spacers or other masking layers), which is helpful in tuning the distribution of the electric field within the photonic device. A further benefit is that the self-alignment processes can ensure that the optical absorption layer and charging layer are formed in a more repeatable manner, such that their locations and/or sizes do not vary substantially from device to device, which is desirable in at least a quality control perspective. Other advantages may include compatibility with existing fabrication processes and the ease and low cost of implementation.

One aspect of the present disclosure pertains to a photonic device. The photonic device includes a substrate, a P-type doped component disposed over the substrate, an N-type doped component disposed over the substrate, an optical absorption layer disposed over the substrate, and a charging layer disposed over the substrate. The optical absorption layer is disposed between the P-type doped component and the N-type doped component. The optical absorption layer and the substrate have different material compositions. A charging layer is disposed between the P-type doped component and the N-type doped component. The charging layer has a first side surface that is substantially linear. The first side surface is in direct contact with the optical absorption layer.

Another aspect of the present disclosure pertains to a structure. The structure includes a substrate and a P-type contact disposed over the substrate in a vertical direction. The P-type contact contains silicon. The structure further includes an N-type contact disposed over the substrate in the vertical direction. The N-type contact contains silicon. The structure also includes an optical absorption layer disposed over the substrate in the vertical direction and between the P-type contact and the N-type contact in a horizontal direction. The optical absorption layer contains germanium. The structure further includes a charging layer disposed over the substrate in the vertical direction and between the optical absorption layer and the N-type contact in the horizontal direction. The charging layer contains silicon that is doped with a P-type dopant. An interface between the optical absorption layer and the charging layer extends substantially in the vertical direction.

Yet another aspect of the present disclosure pertains to a method. A semiconductor layer is formed over a substrate. An opening is etched in the semiconductor layer. Using a selective growth process, an optical absorption layer is formed on a portion of the semiconductor layer exposed by the opening. A charging layer is formed that is directly abutting the optical absorption layer. A passivation layer is formed over the optical absorption layer and the charging layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate;
a first doped contact disposed over the substrate, wherein the first doped contact includes a first recess;
a second doped contact disposed over the substrate, wherein the second doped contact includes a second recess;
an optical absorption layer disposed over the substrate;
a charging layer disposed over the substrate, wherein the optical absorption layer is disposed between the first doped contact and the charging layer, wherein the charging layer is disposed between the second doped contact and the optical absorption layer; and
a passivation layer disposed over the first doped contact, the second doped contact, the optical absorption layer, and the charging layer, wherein a first portion of the passivation layer protrudes into the first recess, and wherein a second portion of the passivation layer protrudes into the second recess.

2. The structure of claim 1, wherein optical absorption layer and the charging layer form an interface that has a substantially vertical component.

3. The structure of claim 1, wherein:
the first doped contact is P-doped;
the second doped contact is N-doped;
the optical absorption layer contains germanium;
the charging layer contains silicon; and
the passivation layer contains a dielectric material.

4. The structure of claim 1, wherein the second recess is further defined by a portion of the charging layer.

5. The structure of claim 4, further comprising a semiconductor layer disposed between the charging layer and the second doped contact, wherein the second recess is further defined by a portion of the semiconductor layer.

6. The structure of claim 1, further comprising an insulator layer disposed between an upper surface of the substrate and bottom surfaces of the first doped contact, the second doped contact, the optical absorption layer, and the charging layer.

7. The structure of claim 1, further comprising a plurality of material layers disposed over the optical absorption layer, wherein the plurality of material layers includes at least a semiconductor layer and a dielectric layer.

8. The structure of claim 7, wherein the passivation layer extends to side surfaces of each of the plurality of material layers and an upper portion of a side surface of the optical absorption layer.

9. A structure, comprising:
a substrate;
a first doped contact disposed over the substrate, wherein the first doped contact contains a first type of dopant;
a second doped contact disposed over the substrate, wherein the second doped contact contains a second type of dopant different from the first type;
a third doped contact disposed over the substrate, wherein the third doped contact contains the second type of dopant and has a greater dopant concentration level than the second doped contact;
an optical absorption layer disposed over the substrate and between the first doped contact and the second doped contact;
a spacer disposed on a portion of a side surface of the optical absorption layer; and
a charging layer disposed over the substrate and below the spacer, wherein the charging layer is disposed between the optical absorption layer and the second doped contact.

10. The structure of claim 9, wherein:
the first type of dopant is a P-type dopant;
the second type of dopant is an N-type dopant;
the optical absorption layer contains germanium; and
the charging layer contains silicon.

11. The structure of claim 9, further comprising:
a silicon layer disposed over the optical absorption layer;
a dielectric layer disposed over the silicon layer; and
a polysilicon layer disposed over the dielectric layer.

12. The structure of claim 11, wherein the spacer is further disposed on side surfaces of the silicon layer, the dielectric layer, and the polysilicon layer.

13. The structure of claim 9, wherein the optical absorption layer and the charging layer form an interface that has a substantially vertical component.

14. The structure of claim 9, wherein a width of the spacer is substantially similar to a width of the charging layer.

15. The structure of claim 9, further comprising a passivation layer disposed over the first doped contact, the second doped contact, the third doped contact, the optical absorption layer, and the charging layer, wherein the passivation layer protrudes vertically into the first doped contact, the second doped contact, and the third doped contact.

16. A structure, comprising:
a substrate;
a first doped contact disposed over the substrate in a cross-sectional side view, wherein the first doped contact contains a first type of dopant;
a second doped contact disposed over the substrate in the cross-sectional side view, wherein the second doped contact contains a second type of dopant different from the first type;
a semiconductor component disposed over the substrate and between the first doped contact and the second doped contact in the cross-sectional side view;
an optical absorption layer disposed over the semiconductor component and between the first doped contact and the second doped contact in the cross-sectional side view, wherein the optical absorption layer is wider than the semiconductor component in the cross-sectional side view;
a plurality of material layers disposed over the optical absorption layer in the cross-sectional side view, wherein the plurality of material layers include at least a semiconductor material and a dielectric material;
a spacer disposed on side surfaces of the plurality of material layers and an upper portion of a side surface of the optical absorption layer in the cross-sectional side view; and
a charging layer disposed over the substrate and below the spacer in the cross-sectional side view, wherein a first side surface of the charging layer extends to the optical absorption layer and the semiconductor component, and wherein a second side surface of the charging layer extends to the second doped contact.

17. The structure of claim 16, further comprising a third doped contact disposed over the substrate, wherein the second doped contact is disposed between the first doped contact and the third doped contact in the cross-sectional side view, and wherein the third doped contact contains the second type of dopant and has a greater dopant concentration level than the second doped contact.

18. The structure of claim 16, wherein the plurality of material layers include:
a silicon layer disposed over the optical absorption layer in the cross-sectional side view;
a dielectric layer disposed over the silicon layer in the cross-sectional side view; and
a polysilicon disposed over the dielectric layer in the cross-sectional side view.

19. The structure of claim 16, further comprising a passivation layer disposed over the first doped contact, the second doped contact, and an uppermost one of the plurality of material layers, wherein portions of the passivation layer protrudes vertically into at least one of the first doped contact or the second doped contact.

20. The structure of claim 16, wherein the first side surface of the charging layer has a substantially straight profile in the cross-sectional side view.
